(19) United States
(12) Patent Application Publication
(10) Pub. No.: US 2024/0379579 A1
(43) Pub. Date: Nov. 14, 2024

(54) SEMICONDUCTOR DEVICE AND MANUFACTURING METHOD THEREOF

(71) Applicant: DYNAX SEMICONDUCTOR, INC., Kunshan (CN)

(72) Inventors: Yi PEI, Kunshan (CN); Xiao HAN, Kunshan (CN); Yuan LI, Kunshan (CN); Guangze XU, Kunshan (CN)

(21) Appl. No.: 18/260,162

(22) PCT Filed: Dec. 29, 2021
(86) PCT No.: PCT/CN2021/142541

§ 371 Date: Jun. 30, 2023

(30) Foreign Application Priority Data
Dec. 31, 2020 (CN) 202011629130.3
Dec. 31, 2020 (CN) 202011629151.5
Dec. 31, 2020 (CN) 202011635286.2

(51) Int. Cl. H01L 23/552; H01L 23/00; H01L 29/20; H01L 29/778

(52) U.S. Cl. CPC H01L 23/552; H01L 24/05; H01L 29/2003; H01L 29/7786; H01L 2224/05553; H01L 2924/1033; H01L 2924/13064; H01L 2924/30105

(57) ABSTRACT

Embodiments of the present disclosure disclose a semiconductor device and a manufacturing method thereof. The semiconductor device includes an active region and a passive region surrounding the active region. The semiconductor device further includes a substrate, a multi-layer semiconductor layer located on one side of the substrate, and at least one shielding structure located on one side of the substrate, the shielding structure being electrically connected to a preset potential, for forming an electric field or a zero electric field of the active region pointing toward the passive region.

### CROSS REFERENCE TO RELATED APPLICATIONS

This patent application is a National Stage Entry of PCT/CN2021/142541 filed on Dec. 29, 2021, which claims the benefit and priority of Chinese Patent Application No. 202011629130.3 filed on Dec. 31, 2020, Chinese Patent Application No. 202011629151.5 filed on Dec. 31, 2020, and Chinese Patent Application No. 202011635286.2 filed on Dec. 31, 2020, the disclosures of which are incorporated by reference herein in their entirety as part of the present application.

### BACKGROUND

Embodiments of the present disclosure relate to the technical field of semiconductors, and in particular to a semiconductor device and a manufacturing method thereof.

After a semiconductor chip is manufactured, the semiconductor chip needs to be packaged to form a semiconductor device. Generally, semiconductor devices are packaged by patch method, and due to the low cost of patch silver paste in the semiconductor device patch method, a method of patch silver paste is generally used to electrically connect some metal connection electrodes in the semiconductor device to the metal electrodes in the packaging shell through the patch silver paste.

However, the patch silver paste may lead to electrochemical migration of silver ions under the action of an electric field, so that the silver ions are migrated to the front surface of the semiconductor chip, and are contacted with other electrodes in the central area of the front surface of the semiconductor chip, resulting in increased leakage or even short circuit, resulting in the failure of normal use of the semiconductor device.

### BRIEF DESCRIPTION

On that account, embodiments of the present disclosure provide a semiconductor device and a manufacturing method thereof, by setting a shielding structure and electrically connecting the shielding structure to a preset potential, an electric field or a zero electric field of the active region pointing toward the non-active region can be formed, effectively shielding silver ions and inhibiting them from migrating to the central area of the front surface of the semiconductor chip, and obtaining a semiconductor device with stable performance.

In a first aspect, an embodiment of the present disclosure provides a semiconductor device, including an active region and a non-active region surrounding the active region. The semiconductor device further includes a substrate, a multi-layer semiconductor layer located on one side of the substrate, and at least one shielding structure located on one side of the substrate, the shielding structure being electrically connected to a preset potential, for forming an electric field or a zero electric field of the active region pointing toward the non-active region.

The multi-layer semiconductor layer may include a conductive region located in the non-active region and a two-dimensional electron gas elimination region, the two-dimensional electron gas elimination region being located between the conductive region being as the shielding structure, and the active region, and/or the semiconductor device may further include a dielectric layer located on one side of the multi-layer semiconductor layer away from the substrate, and at least one conductive trace being as the shielding structure, located on one side of the dielectric layer away from the multi-layer semiconductor layer.

The shielding structure at least may include a first shielding subsection, the first shielding subsection being located on one side of the non-active region away from the active region.

The shielding structure may further include a second shielding subsection and a third shielding subsection. The first shielding subsection is electrically connected to the second shielding subsection and the third shielding subsection respectively, and extending direction of the first shielding subsection intersects both extending direction of at least part of the second shielding subsection and extending direction of at least part of the third shielding subsection; and the shielding structure is located on at least three sides of the non-active region away from the active region.

The shielding structure may include a fourth shielding subsection extending along a first direction and a fifth shielding subsection extending along a second direction, the first direction and the second direction intersect both are parallel to the plane where the substrate is located. The fourth shield subsection includes a plurality of first sub-shielding structures, two of the first sub-shielding structures adjacent along the first direction are arranged staggered in the second direction, and vertical projections on the first plane overlap, and the first plane is parallel to the first direction and perpendicular to the plane where the substrate is located, and/or, the fifth shield subsection includes a plurality of second sub-shielding structures, two of the second sub-shielding structures adjacent along the second direction are arranged staggered in the first direction, and vertical projections on the second plane overlap, and the second plane is parallel to the second direction and perpendicular to the plane where the substrate is located.

At least part of the shielding structure is not provided with a dielectric layer on one side away from the substrate.

The multi-layer semiconductor layer may include a conductive region located in the non-active region and a two-dimensional electron gas elimination region, and the conductive region is a two-dimensional electron gas forming region or a semiconductor doped region.

The semiconductor device may further include a gate located on one side of the multi-layer semiconductor layer away from the substrate, and located in the active region. The semiconductor device further may include a gate bonding pad located on one side of the multi-layer semiconductor layer away from the substrate, and located in the non-active region, the gate bonding pad being electrically connected to the gate, and at least one shielding structure includes a gate shielding structure for shielding and protecting the gate bonding pad, potential of the preset potential is greater than or equal to 0.

The semiconductor device may further include a drain located on one side of the multi-layer semiconductor layer away from the substrate, and located in the active region. The semiconductor device further includes a drain bonding pad located on one side of the multi-layer semiconductor layer away from the substrate, and located in the non-active region, the drain bonding pad being electrically connected to the drain, and at least one shielding structure includes a drain shielding structure for shielding and protecting the drain bonding pad, and potential of the preset potential is greater than or equal to 0.

In a second aspect, an embodiment of the present disclosure provides a method of manufacturing a semiconductor device according to the aspect above, including providing a substrate, forming a multi-layer semiconductor layer on one side of the substrate, and forming at least one shielding structure on one side of the substrate, the shielding structure being electrically connected to a preset potential, for forming an electric field or a zero electric field of the active region pointing toward the non-active region.

With the semiconductor device provided by embodiments of the present disclosure, by adding a shielding structure and electrically connecting the shielding structure to a preset potential, an electric field or a zero electric field of the active region pointing toward the non-active region can be formed, effectively shielding silver ions and inhibiting them from migrating to the central area of the front surface of the semiconductor chip, and ensuring the normal operation of the semiconductor device.

In a third aspect, an embodiment of the present disclosure provides a semiconductor device, including a working region and a scribe region surrounding the working region. The working region includes an active region and a passive region surrounding the active region. The semiconductor device further includes a substrate, a multi-layer semiconductor layer located on one side of the substrate, at least one bonding pad located on one side of the multi-layer semiconductor layer away from the substrate, and located in the passive region, and at least one shielding structure located on one side of the multi-layer semiconductor layer away from the substrate, the shielding structure being for shielding and protecting the bonding pad, wherein the shielding structure is electrically connected to a preset potential, and the preset potential U satisfies U≥0.

The semiconductor device may further include a gate located on one side of the multi-layer semiconductor layer away from the substrate, and located in the active region, at least one bonding pad includes a gate bonding pad electrically connected to the gate, and at least one shielding structure includes a gate shielding structure, and the gate shielding structure is for shielding and protecting the gate bonding pad.

The semiconductor device may further include a drain located on one side of the multi-layer semiconductor layer away from the substrate, and located in the active region, at least one bonding pad further includes a drain bonding pad electrically connected to the drain, and at least one shielding structure includes a drain shielding structure, and the drain shielding structure is for shielding and protecting the drain bonding pad.

The active region may further include a plurality of fixed potential structures, and the shielding structure is electrically connected to the fixed potential structures.

The fixed potential structure may include a source, and the shielding structure is electrically connected to the source.

The shielding structure may include a gate shielding structure, and the fixed potential structure includes a drain, and the gate shielding structure is electrically connected to the drain.

The source may include a first source and an Nth source arranged along a first direction, the first direction being parallel to the plane where the substrate is located, the first source is located at a first end of the active region, and the Nth source is located at a second end of the active region, the first end and the second end being disposed opposite to each other along the first direction, and the shielding structure is electrically connected to the first source and the Nth source respectively, and the gate bonding pad is located in an interval defined by the shielding structure and the active region.

The source may be electrically connected to a source back electrode through a via hole, overlapping area of vertical projection of the shielding structure on the plane where the substrate is located and vertical projection of the via hole on the plane where the substrate is located is S1, and vertical projection area of the via hole on the plane where the substrate is located is S2, where S1<S2/4.

The vertical projection of the shielding structure on the plane where the substrate is located does not overlap with the vertical projection of the via hole on the plane where the substrate is located.

The shielding structure may include a first shielding subsection, a second shielding subsection, and a third shielding subsection, the second shielding subsection being connected to the first shielding subsection and the third shielding subsection respectively, and the second shielding subsection is located in the scribe region, the first shielding subsection is located in the working region and is electrically connected to the first source, and the third shielding subsection is located in the working region and is electrically connected to the Nth source.

The semiconductor device may further include a first dielectric layer located on one side of the multi-layer semiconductor layer away from the substrate, and located in the passive region, the first shielding subsection and the third shielding subsection both are located on one side of the first dielectric layer away from the substrate, and along a direction perpendicular to the substrate, thickness of the shielding structure is greater than that of the first dielectric layer, so that the first shielding subsection and the third shielding subsection both are electrically connected to the second shielding subsection.

The semiconductor device may further include a first dielectric layer located on one side of the multi-layer semiconductor layer away from the substrate, and located in the passive region, and along a direction perpendicular to the substrate, thickness of the source is greater than that of the first dielectric layer, so that the first shielding subsection and the third shielding subsection both are electrically connected to the source.

The semiconductor device may further include a second dielectric layer located in the working region, the second dielectric layer covers the first shielding subsection, the third shielding subsection and the source, and in the direction perpendicular to the substrate, sum of thicknesses of the first dielectric layer, the first shielding subsection, and the second dielectric layer is greater than thickness of the source, so that the second dielectric layer located on one side of the first shielding subsection away from the substrate is connected to the second dielectric layer located on one side of the source away from the substrate.

The shielding structure may include a first shielding subsection, a second shielding subsection, and a third shielding subsection, the second shielding subsection being connected to the first shielding subsection and the third shielding subsection respectively, and the first shielding subsection, the second shielding subsection, and the third shielding subsection are all located in the working region, the first shielding subsection is electrically connected to the first source, and the third shielding subsection is electrically connected to the Nth source.

The semiconductor device may further include at least one dielectric layer located on one side of the multi-layer semiconductor layer away from the substrate, and located in the passive region, at least one of the dielectric layers includes a first surface on one side of the multi-layer semiconductor layer away from the substrate, the shielding structure includes a second surface on one side of the multi-layer semiconductor layer away from the substrate, and along a direction perpendicular to the substrate, the second surface is located on one side of the first surface away from the substrate.

The source may include a multi-layer source metal layer, and the shielding structure may include a one-layer shielding metal layer, and the shielding metal layer and one side of the multi-layer source metal layer are provided on the same layer and made of the same material, or the shielding structure may include a multi-layer shielding metal layer, and the multi-layer shielding metal layer corresponds to the multi-layer source metal layer one by one, and the shielding metal layer and the source metal layer set correspondingly are provided on the same layer and made of the same material.

In a fourth aspect, an embodiment of the present disclosure further provides a method of manufacturing a semiconductor device according to any of the aspects above, including providing a substrate, forming a multi-layer semiconductor layer on one side of the substrate, forming at least one bonding pad on one side of the multi-layer semiconductor layer away from the substrate, and in the passive region, and forming at least one shielding structure on one side of the multi-layer semiconductor layer away from the substrate, the shielding structure being for shielding and protecting the bonding pad, wherein the shielding structure is electrically connected to a preset potential, and the preset potential U satisfies U≥0.

With the semiconductor device provided by embodiments of the present disclosure, by adding a shielding structure and electrically connecting the shielding structure to a preset potential, silver ions in the patch silver paste are effectively shielded from migrating to the bonding pad during the packaging process, ensuring the stable performance of the bonding pad and the electrodes connected to the bonding pad, avoiding the short circuit between the bonding pad as well as the electrode connected to the bonding pad and the source, and ensuring the normal operation of the semiconductor device.

In a fifth aspect, an embodiment of the present disclosure provides a semiconductor device, including a working region and a scribe region surrounding the working region, the working region includes an active region and a passive region surrounding the active region, the semiconductor device further includes a substrate, a multi-layer semiconductor layer located on one side of the substrate, a gate located on one side of the multi-layer semiconductor layer away from the substrate, and located in the active region, at least one bonding pad located on one side of the multi-layer semiconductor layer away from the substrate, and located in the passive region, the bonding pad including at least a gate bonding pad, and the gate bonding pad being electrically connected to the gate, and at least one shielding structure located on one side of the multi-layer semiconductor layer away from the substrate, the shielding structure including a gate shielding structure, and the gate shielding structure being for shielding and protecting the gate bonding pad.

The semiconductor device may further include a drain located on one side of the multi-layer semiconductor layer away from the substrate, and located in the active region, the bonding pad further includes a drain bonding pad, and the drain bonding pad is electrically connected to the drain, and the shielding structure may further include a drain shielding structure, and the drain shielding structure is for shielding and protecting the drain bonding pad.

The shielding structure may be electrically connected to a preset potential, and the preset potential U satisfies U≥0.

The active region may further include a plurality of fixed potential structures, and the shielding structure is electrically connected to the fixed potential structures.

The shielding structure may include a first shielding subsection, a second shielding subsection, and a third shielding subsection, the second shielding subsection being connected to the first shielding subsection and the third shielding subsection respectively, shape of the connection between the first shielding subsection and the second shielding subsection includes an “L” shape or a “T” shape, and shape of the connection between the third shielding subsection and the second shielding subsection includes an “L” shape or a “T” shape.

The shielding structure may include a first portion extending along a first direction and a second portion extending along a second direction, the first direction and the second direction both are parallel to the plane where the substrate is located, and the first direction intersects the second direction, and connection angle between the first portion and the second portion includes a chamfer or an arc angle, or the shielding structure further includes a third portion connected to the first portion and the second portion respectively, and the angle between the third portion and the first portion is an obtuse angle, and the angle between the third portion and the second portion is an obtuse angle.

The shielding structure may include a first portion extending along a first direction and a second portion extending along a second direction, the first direction and the second direction both are parallel to the plane where the substrate is located, and the first direction intersects the second direction. The semiconductor device includes a first boundary extending along the first direction and a second boundary extending along the second direction, minimum distance L1 between the first portion and the first boundary satisfies L1>30 μm, and minimum distance L2 between the second portion and the second boundary satisfies L2>30 μm.

The shielding structure may include a first portion extending along a first direction and a second portion extending along a second direction, the first direction and the second direction both are parallel to the plane where the substrate is located, and the first direction intersects the second direction, extension width D1 of the first portion in the second direction satisfies D1>10 μm, and extension width D2 of the second portion in the first direction satisfies D2>10 μm.

Minimum distance L3 between vertical projection of the shielding structure on the plane where the substrate is located and vertical projection of the gate bonding pad on the plane where the substrate is located satisfies L3>10 μm, and minimum distance L4 between vertical projection of the shielding structure on the plane where the substrate is located and vertical projection of the drain bonding pad on the plane where the substrate is located satisfies L4>10 μm.

In a sixth aspect, an embodiment of the present disclosure further provides a method of manufacturing a semiconductor device according to any of the aspects above, including providing a substrate, forming a multi-layer semiconductor layer on one side of the substrate, forming a gate on one side of the multi-layer semiconductor layer away from the substrate, and in the active region, forming at least one bonding pad on one side of the multi-layer semiconductor layer away from the substrate, and in the passive region, the bonding pad including at least a gate bonding pad, and the gate bonding pad being electrically connected to the gate, and forming at least one shielding structure on one side of the multi-layer semiconductor layer away from the substrate, the shielding structure including a gate shielding structure, and the gate shielding structure being for shielding and protecting the gate bonding pad.

With the semiconductor device provided by embodiments of the present disclosure, by adding a shielding structure, silver ions in the patch silver paste are effectively shielded from migrating to the bonding pad during the packaging process, ensuring the stable performance of the bonding pad and the electrodes connected to the bonding pad, avoiding the short circuit between the bonding pad as well as the electrode connected to the bonding pad and the source, and ensuring the normal operation of the semiconductor device.

### BRIEF DESCRIPTION OF THE DRAWINGS

FIG. 1 is a schematic diagram illustrating the structure of a semiconductor device in the prior art;

FIG. 2 is a top view schematic diagram illustrating a semiconductor device according to an embodiment of the present disclosure;

FIG. 3 is a top view schematic diagram illustrating another semiconductor device according to an embodiment of the present disclosure:

FIG. 4 is a top view schematic diagram illustrating another semiconductor device according to an embodiment of the present disclosure:

FIG. 5 is a cross-sectional schematic diagram illustrating a semiconductor device taken along AA′ in FIG. 2;

FIG. 6 is a cross-sectional schematic diagram illustrating another semiconductor device taken along AA′ in FIG. 2;

FIG. 7 is a cross-sectional schematic diagram illustrating another semiconductor device taken along AA′ in FIG. 2;

FIG. 8 is a cross-sectional schematic diagram illustrating another semiconductor device taken along AA′ in FIG. 2:

FIG. 9 is a top view schematic diagram illustrating another semiconductor device according to an embodiment of the present disclosure;

FIG. 10 is a top view schematic diagram illustrating another semiconductor device according to an embodiment of the present disclosure:

FIG. 11 is a top view schematic diagram illustrating a semiconductor device according to an embodiment of the present disclosure;

FIG. 12 is a top view schematic diagram illustrating another semiconductor device according to an embodiment of the present disclosure:

FIG. 13 is a top view schematic diagram illustrating another semiconductor device according to an embodiment of the present disclosure;

FIG. 14 is a top view schematic diagram illustrating another semiconductor device according to an embodiment of the present disclosure;

FIG. 15 is a cross-sectional schematic diagram illustrating the semiconductor device provided in FIG. 14 along the section line A-A′:

FIG. 16 is a cross-sectional schematic diagram illustrating the semiconductor device provided in FIG. 14 along the section line B-B′:

FIG. 17 is a top view schematic diagram illustrating another semiconductor device according to an embodiment of the present disclosure:

FIG. 18 is a cross-sectional schematic diagram illustrating the semiconductor device provided in FIG. 17 along the section line C-C′:

FIG. 19 is a top view schematic diagram illustrating another semiconductor device according to an embodiment of the present disclosure:

FIG. 20 is a top view schematic diagram illustrating another semiconductor device according to an embodiment of the present disclosure:

FIG. 21 is a partial top view schematic diagram illustrating a shielding structure according to an embodiment of the present disclosure; and

FIG. 22 is a partial top view schematic diagram illustrating another shielding structure according to an embodiment of the present disclosure.

### DETAILED DESCRIPTION

The present disclosure will be further described in detail below in conjunction with the accompanying drawings and embodiments. It should be understood that the specific embodiments described herein are merely illustrative of the present disclosure and are not intended to limit the scope thereof. Additionally, it should be noted that, for ease of description, the accompanying drawings only show the parts relevant to the present disclosure rather than the entire structure.

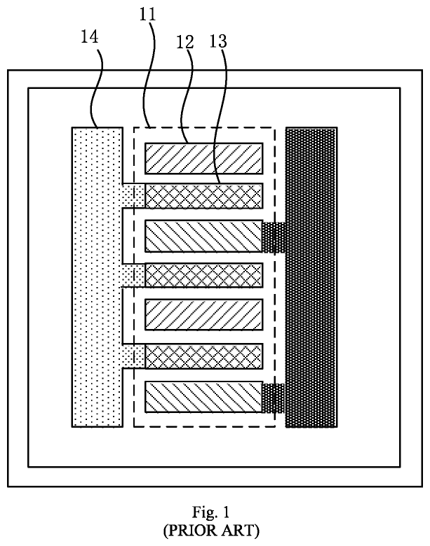

Exemplarily, FIG. 1 is a schematic diagram illustrating the structure of a semiconductor device in the prior art. As shown in FIG. 1, the semiconductor device includes a source 12 and a gate 13 located in the active region 11, as well as a gate bonding pad 14 located in the passive region, the gate bonding pad 14 is electrically connected to a plurality of gates 13, and the source 12 is electrically connected to a source back electrode (not shown in the drawing) through a via hole. When packaging to form a semiconductor device, the source back electrode is electrically connected to the electrode in the packaging shell through the patch silver paste. The patch silver paste may lead to electrochemical migration of silver ions under the action of an electric field, so that the silver ions are migrated to the front surface of the semiconductor chip, and are contacted with the gate in the central area of the front surface of the semiconductor chip, resulting in increased leakage or even short circuit between the gate 13 and the source 12, resulting in the failure of normal use of the semiconductor device.

Based on the above problem, embodiments of the present disclosure provide a semiconductor device, including an active region and a non-active region surrounding the active region. The semiconductor device further includes a substrate, a multi-layer semiconductor layer located on one side of the substrate, and at least one shielding structure located on one side of the substrate, the shielding structure being electrically connected to a preset potential, for forming an electric field or a zero electric field of the active region pointing toward the non-active region. By adopting the technical solution above, by arranging the shielding structure to be electrically connected to the preset potential, an electric field or a zero electric field that inhibits silver ions from migrating to the central area of the front surface of the semiconductor chip can be generated to ensure the normal operation of the semiconductor device.

The above is the core idea of the present disclosure, and the technical solutions in the embodiments of the present disclosure will be clearly and completely described below in conjunction with the drawings in the embodiments of the present disclosure. Based on the embodiments of the present disclosure, all other embodiments obtained by persons of ordinary skill in the art without making creative efforts belong to the protection scope of the present disclosure.

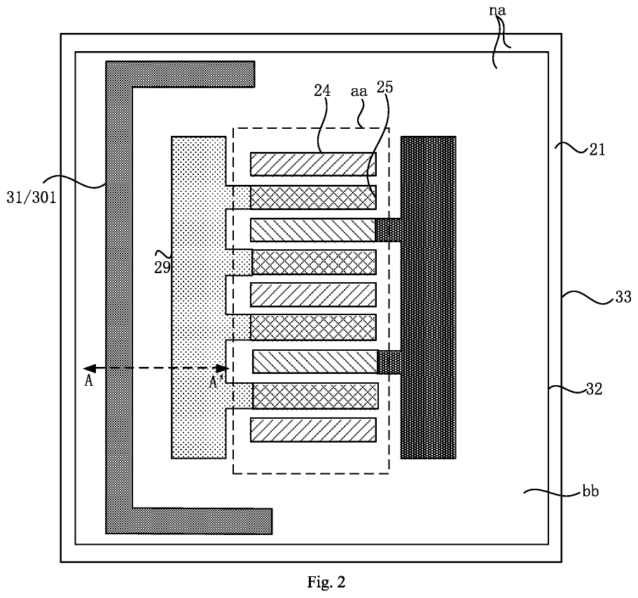

FIG. 2 is a top view schematic diagram illustrating a semiconductor device according to an embodiment of the present disclosure. The semiconductor device provided by the embodiment of the present disclosure includes an active region aa and a non-active region na surrounding the active region. The semiconductor device further includes a substrate 21, a multi-layer semiconductor layer (not shown) located on one side of the substrate 21, and at least one shielding structure 31 located on one side of the substrate, the shielding structure 31 being electrically connected to a preset potential (not shown), for forming an electric field or a zero electric field of the active region aa pointing toward the non-active region na.

Wherein, the non-active region na refers to a region other than the active region aa. Referring to FIG. 2, the semiconductor device includes a working region 32 and a scribe region 33 surrounding the working region. The working region 32 includes the active region aa and the passive region bb surrounding the active region, where the “non-active region na” specifically refers to the scribe region 33 and the passive region bb in the working region 32.

Specifically, the working region 32 may be understood as the region where the semiconductor device works, which includes the active region aa and the passive region bb. The active region aa may be understood as the region where two-dimensional electron gas, electrons or holes exist, and its working state and characteristics are affected by external circuits, which is the active working region of the semiconductor device. The passive region bb may be understood as the region outside the active region aa that participates in the operation of the device, but the working state is not affected by external circuits. The scribe region 33 refers to the region where a semiconductor device is diced and cut to form a plurality of independent semiconductor devices.

The semiconductor device usually further includes a gate, a source, and a drain located on one side of the semiconductor layer away from the substrate, and located in the active region aa. Typically, the gate is negatively biased, the drain is positively biased, and the source is zero. Due to the potential difference between the source and the gate, an electric field will be formed from the edge of the semiconductor chip to the central area, so that the silver ions migrate to the central area of the semiconductor chip to contact the gate, which leads to increased leakage or even a short circuit between the gate and the source. Similarly, when silver ions migrate, they may also contact the drain, resulting in increased leakage or even a short circuit between the drain and source. Therefore, in order to ensure stable performance of the semiconductor device, the shielding structure may be a gate shielding structure for shielding and protecting the gate, and/or the shielding structure is a drain shielding structure, for shielding and protecting the drain, which is not specifically limited in this embodiment of the present disclosure.

Further, the semiconductor device usually further includes an electrode connection structure located on one side of the semiconductor layer away from the substrate, and located in the passive region bb, such as a bonding pad, which specifically may include a gate bonding pad and a drain bonding pad, wherein the gate bonding pad is electrically connected to the gate, and the drain bonding pad is electrically connected to the drain. Adaptively, the gate shielding structure may shield and protect the gate bonding pad, thereby achieving shielding and protection for the gate, and the drain shielding structure may shield and protect the drain bonding pad, thereby achieving shielding and protection for the drain.

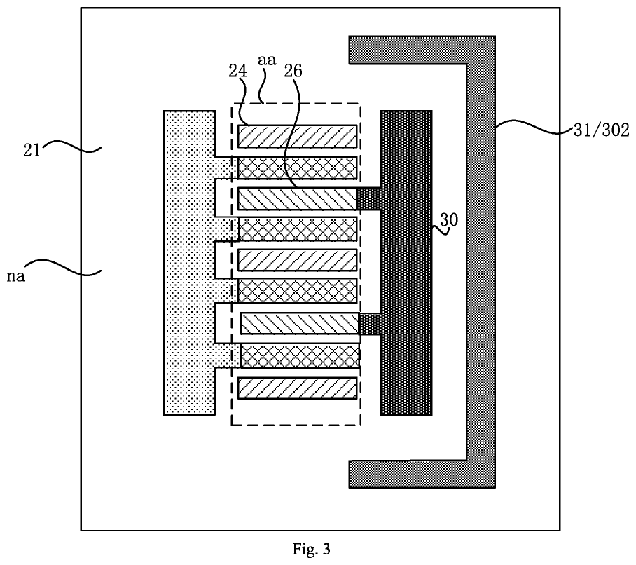

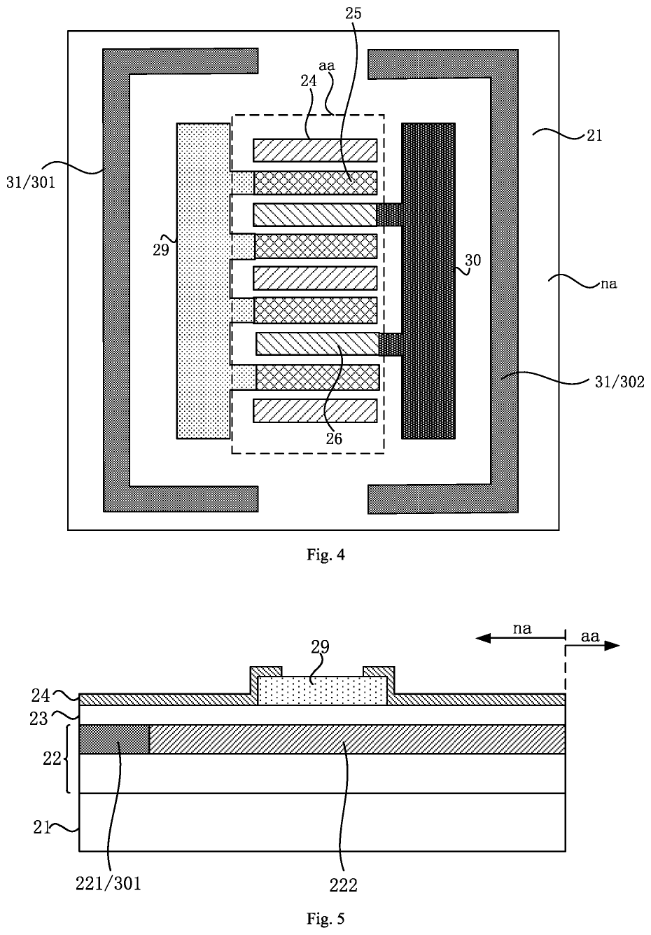

Exemplarily, FIG. 2 takes the bonding pad as a gate bonding pad 29 and the shielding structure 31 as a gate shielding structure 301 as an example for illustration. Exemplarily, FIG. 3 is a top view schematic diagram illustrating another semiconductor device according to an embodiment of the present disclosure, and FIG. 3 takes the bonding pad as a drain bonding pad 30 and the shielding structure 31 as a drain shielding structure 302 as an example for illustration. FIG. 4 is a top view schematic diagram illustrating another semiconductor device according to an embodiment of the present disclosure, and FIG. 4 takes the bonding pad including a gate bonding pad 29 and a drain bonding pad 30, and the shielding structure 31 including a gate shielding structure 301 and a drain shielding structure 302 as an example for illustration.

Further, the shielding structure 31 is electrically connected to a preset potential, which may form an electric field or a zero electric field of the active region aa pointing toward the non-active region na, so that the electric field or zero electric field may be used to inhibit the silver ions from migrating to the central area of the front surface of the semiconductor chip.

Specifically, since silver ions cannot move under a zero electric field, zero electric field may shield silver ions and inhibit their migration to the central area of the semiconductor chip. Moreover, the direction of the electric field is such that the active region aa points toward the non-active region na, so silver ions can be inhibited from migrating to the central area of the semiconductor chip.

Further, the preset potential may be either introduced by an external power source, or a fixed potential structure directly connected to the active region aa, which is not limited in the embodiment of the present disclosure.

It should be noted that the active region aa pointing toward the non-active region na only indicates the direction of the electric field or zero electric field, and does not indicate the region where the electric field or zero electric field is located. The region where the electric field or zero electric field is located is specifically the region between the shielding structure and the outer edge of the non-active region na.

Further, the shielding structure 31 may be disposed in the working region 32 and/or the scribe region 33, which is not limited in the embodiment of the present disclosure.

Exemplarily, FIG. 2 takes the shielding structure 31 (gate shielding structure 301) disposed in the working region 32 as an example for illustration, so that the semiconductor device including the shielding structure 31 may be arranged compactly, and the semiconductor device has a small volume, which is conducive to realizing the miniaturization design of the semiconductor device. In other embodiments, the shielding structure 31 may further be disposed in the scribe region 33. In this way, under the premise of shielding silver ions, it is ensured that the setting of the shielding structure 31 will not affect the normal operation of the semiconductor device, and the stable performance of the semiconductor device is ensured. In addition, the shielding structure 31 may further be partially disposed in the working region 32 and partially disposed in the scribe region 33, which is not limited in this embodiment of the present disclosure.

To sum up, with the semiconductor device provided by embodiments of the present disclosure, by adding a shielding structure and electrically connecting the shielding structure to a preset potential, an electric field or a zero electric field of the active region pointing toward the non-active region can be formed, effectively shielding silver ions and inhibiting them from migrating to the central area of the front surface of the semiconductor chip, and ensuring the normal operation of the semiconductor device.

On the basis of the above embodiments, referring to FIG. 2, the semiconductor device may further include a gate 25 located on one side of the multi-layer semiconductor layer away from the substrate 21, and located in the active region aa. The semiconductor device further includes a gate bonding pad 29 located on one side of the multi-layer semiconductor layer away from the substrate 21, and located in the non-active region na, and the gate bonding pad 29 is electrically connected to the gate 25. The at least one shielding structure 31 includes a gate shielding structure 301, and the gate shielding structure 301 is for shielding and protecting the gate bonding pad 29. At the time, the potential of the preset potential is greater than or equal to 0.

As shown in FIG. 2, the semiconductor device further includes a gate 25, which is electrically connected to a gate bonding pad 29, the gate shielding structure 301 is for shielding and protecting the gate bonding pad 29 and the gate 25, and inhibits silver ions in the patch silver paste from migrating to the gate bonding pad 29 during the packaging process, which may results in increased leakage or even a short circuit between the gate 25 and the source 24, affect the performance of the gate bonding pad 29 and the gate 25, affect the performance of the semiconductor device, and result in the failure of normal use of the semiconductor device.

Referring to FIG. 4, further the semiconductor device may further include a drain 26 located on one side of the multi-layer semiconductor layer away from the substrate 21, and located in the active region aa. The semiconductor device further includes a drain bonding pad 30 located on one side of the multi-layer semiconductor layer away from the substrate 21, and located in the non-active region na, and the drain bonding pad 30 is electrically connected to the drain 26, the at least one shielding structure 31 includes a drain shielding structure 302, and the drain shielding structure 302 is for shielding and protecting the drain bonding pad 30, at the time, the potential of the preset potential is greater than or equal to 0.

As shown in FIG. 4, the semiconductor device further includes a gate 25 and a drain 26, the gate 25 is electrically connected to a gate bonding pad 29, the gate shielding structure 301 is for shielding and protecting the gate bonding pad 29 and the gate 25, so as to prevent the silver ions in the patch silver paste from migrating to the gate bonding pad 29 during the packaging process, which may cause the gate 25 and the source 24 to be short-circuited, and affect the performance of the gate bonding pad 29 and the gate 25. The drain 26 is electrically connected to the drain bonding pad 30, and the drain shielding structure 302 is for shielding and protecting the drain bonding pad 30 and the drain 26, and prevents the silver ions in the patch silver paste from migrating to the drain bonding pad 30 during the packaging process, which may result in increased leakage or even a short circuit between the drain 26 and the source 24, affect the performance of the drain bonding pad 30 and the drain 26, affect the performance of the semiconductor device, and result in the failure of normal use of the semiconductor device.

On the basis of the above-mentioned embodiments, the following takes the gate shielding structure 301 as an example of the shielding structure to further describe the specific arrangement of the shielding structure in detail.

The multi-layer semiconductor layer may include a conductive region located in the non-active region na and a two-dimensional electron gas elimination region, the two-dimensional electron gas elimination region is located between the conductive region being as the shielding structure, and the active region, and/or the semiconductor device may further include a dielectric layer located on one side of the multi-layer semiconductor layer away from the substrate, at least one conductive trace being as the shielding structure is provided on one side of the dielectric layer away from the multi-layer semiconductor layer.

As a feasible implementation manner, FIG. 5 is a cross-sectional schematic diagram illustrating a semiconductor device taken along AA′ in FIG. 2. Referring to FIG. 5, the multi-layer semiconductor layer 22 includes a conductive region 221 located in the non-active region na and a two-dimensional electron gas elimination region 222, and the two-dimensional electron gas elimination region 222 is located between the conductive region 221 and the active region, at the time, the conductive region 221 may be used as a shielding structure, such as the gate shielding structure 301, and electrically connected to a preset potential to shield and protect the gate bonding pad 29 and the gate, and prevent the silver ions in the patch silver paste from migrating to the gate bonding pad 29 during the packaging process, which may cause increased leakage or even a short circuit between the gate and the source, and affect the performance of the gate bonding pad 29 and the gate.

Further, when the conductive region 221 is used as a shielding structure, the conductive region 221 is a two-dimensional electron gas forming region or a semiconductor doped region.

Exemplarily, the conductive region 221 may be a two-dimensional electron gas. Specifically, the multi-layer semiconductor layer 22 of the semiconductor device provided by the embodiment of the present disclosure may specifically include a nucleation layer located on the substrate, a buffer layer located on one side of the nucleation layer away from the substrate, a channel layer located on one side of the buffer layer away from the nucleation layer, and a barrier layer located on one side of the channel layer away from the buffer layer, wherein the barrier layer and the channel layer form a heterojunction structure, and a two-dimensional electron gas 2DEG (not shown in the drawing) is formed at the heterojunction interface. Usually, only the active region aa retains the two-dimensional electron gas, and the non-active region na needs to eliminate the two-dimensional electron gas to form a two-dimensional electron gas elimination region 222. In this embodiment, by setting the conductive region 221 as a two-dimensional electron gas, the space occupied by a special shielding structure can be avoided, and the increase in the preparation process can further be avoided, that is, it is only necessary to retain a part of the two-dimensional electron gas at the edge of the semiconductor device when eliminating the two-dimensional electron gas in the non-active region na, and the process is simpler and more efficient. In addition, semiconductor doping may further be performed on the multi-layer semiconductor layer 22 in the non-active region na to form the conductive region 221, which may be set by those skilled in the art according to requirements, which is not limited in the embodiment of the present disclosure.

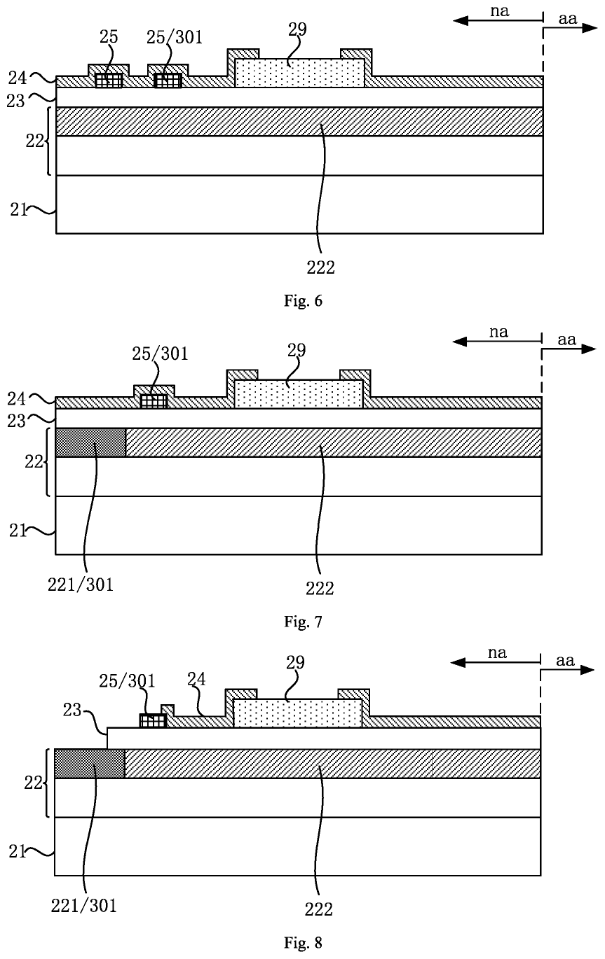

As another feasible implementation manner, FIG. 6 is a cross-sectional schematic diagram illustrating another semiconductor device taken along AA′ in FIG. 2. Referring to FIG. 6, the semiconductor device further includes a dielectric layer 23 located on one side of the multi-layer semiconductor layer 22 away from the substrate 21, one side of the dielectric layer 23 away from the multi-layer semiconductor layer 22 is provided with at least one conductive trace 25, at the time, the conductive wire 25 may be used as a shielding structure (such as the gate shielding structure 301) and electrically connected to a preset potential to shield and protect the gate bonding pad 29 and the gate, and prevent the silver ions in the patch silver paste from migrating to the gate bonding pad 29 during the packaging process, which may cause increased leakage or even a short circuit between the gate and the source, and affect the performance of the gate bonding pad 29 and the gate.

Exemplarily, FIG. 6 takes two conductive traces 25 provided on one side of the dielectric layer 23 away from the multi-layer semiconductor layer 22 as an example for illustration. The conductive wire 25 may be any metal wire with good electrical conductivity, and the material thereof is not limited in the embodiment of the present disclosure. By setting the conductive wire 25 as a shielding structure, effective shielding protection may also be provided for the bonding pad. Moreover, as shown in FIG. 6, on one side of the gate bonding pad 29 away from the substrate, a second dielectric layer 24 is usually provided (“second” is only used for distinction and has no real meaning): the second dielectric layer 24 exposes the gate bonding pad 29 and protects the underlying film structure. Referring to FIG. 5 and FIG. 6, compared to the conductive region 221 in the multi-layer semiconductor layer 22, since the conductive wiring 25 is arranged on one side of the dielectric layer 23 away from the multi-layer semiconductor layer 22, the dielectric layer (only the second dielectric layer 24) above the conductive wiring 25 is thinner, so its influence on the shielding effect of the conductive traces 25 is smaller, that is, the shielding effect of the conductive traces 25 is better.

As another feasible implementation manner, FIG. 7 is a cross-sectional schematic diagram illustrating another semiconductor device taken along AA′ in FIG. 2. Referring to FIG. 7, the multi-layer semiconductor layer 22 includes a conductive region 221 located in the non-active region na and a two-dimensional electron gas elimination region 222 located between the conductive region 221 and the active region, the conductive region 221 serves as a shielding structure (such as the gate shielding structure 301), and is electrically connected to a preset potential (not shown), at the same time, the semiconductor device further includes a dielectric layer 23 located on one side of the multi-layer semiconductor layer 22 away from the substrate 21, at least one conductive wire 25 is provided on one side of the dielectric layer 23 away from the multi-layer semiconductor layer 22, and the conductive wire 25 serves as a shielding structure (such as the gate shielding structure 301) and is electrically connected to a preset potential (not shown).

In this embodiment, by setting the conductive region 221 and the conductive trace 25 as a shielding structure, the shielding effect can be ensured, when one of the shielding structures fails due to external factors, the other shielding structure may further play a good shielding effect, thereby increasing the reliability of the shielding structure, effectively shielding and protecting the bonding pad and ensuring the performance of the semiconductor device. It can be understood that when both the conductive region 221 and the conductive trace 25 serve as a shielding structure, both are connected to the same preset potential.

On the basis of any of the solutions described in the above three possible implementation manners, the setting manner of the shielding structure will be further described below.

FIG. 8 is a cross-sectional schematic diagram illustrating another semiconductor device taken along AA′ in FIG. 2. Referring to FIG. 8, at least part of the shielding structure is not provided with a dielectric layer on one side away from the substrate.

As mentioned above, when a dielectric layer (for example the dielectric layer 23 and the second dielectric layer 24) is provided on one side of the shielding structure (for example the gate shielding structure 301) away from the substrate 21, the dielectric layer will affect the shielding effect of the shielding structure: therefore, in order to avoid weakening the shielding effect of the shielding structure, it is preferable not to provide a dielectric layer on one side of the shielding layer away from the substrate. It should be noted that either part of the shielding structure may be exposed, or all of the shielding structure may be exposed, which is not limited in this embodiment of the present disclosure.

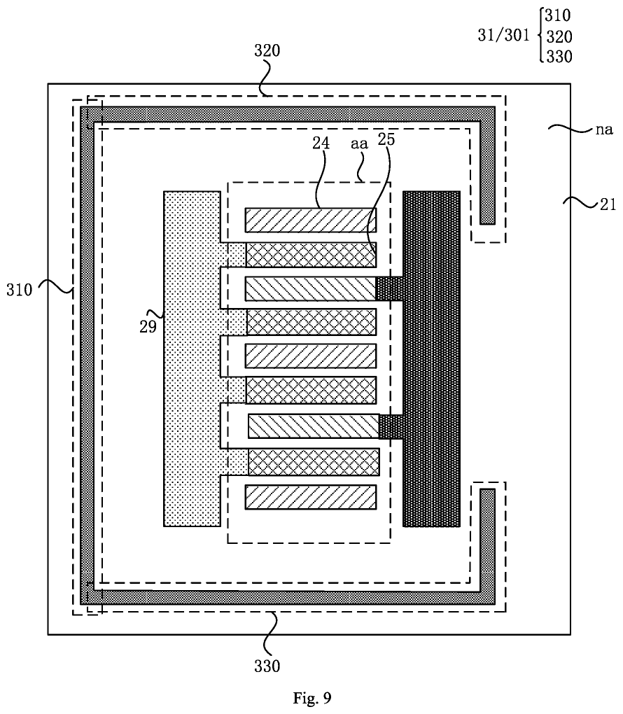

FIG. 9 is a top view schematic diagram illustrating another semiconductor device according to an embodiment of the present disclosure. Referring to FIG. 9, the shielding structure 31 may include at least a first shielding subsection 310, and the first shielding subsection 310 is located on one side of the non-active region na away from the active region aa.

As shown in FIG. 9, the first shielding subsection is located on one of sides of the non-active region na away from the active region aa. FIG. 9 is illustrated by taking the gate shielding structure 301 as an example, by arranging the gate shielding structure 301 on one side of the long side of the gate bonding pad 29, most of the silver ions may be shielded, preventing the silver ions in the patch silver paste from migrating to the gate bonding pad 29 during the packaging process, which may cause increased leakage or even a short circuit between the gate and the source, and affect the performance of the gate bonding pad 29 and the gate.

Continuing referring to FIG. 9, further the shielding structure may further include a second shielding subsection 320 and a third shielding subsection 330. The first shielding subsection 310 is electrically connected to the second shielding subsection 320 and the third shielding subsection 330 respectively, and extending direction of the first shielding subsection 310 intersects both extending direction of at least part of the second shielding subsection 320 and extending direction of at least part of the third shielding subsection 330. The shielding structure 31 is located on at least three sides of the non-active region na away from the active region aa.

As shown in FIG. 9, the gate shielding structure 301 is located on four sides of the non-active region na away from the active region aa. In this way, the gate shielding structure 301 can half-enclose the gate bonding pad 29 to shield the silver ions migrating to the gate bonding pad 29 in all directions, so as to prevent the silver ions in the patch silver paste from migrating to the gate bonding pad 29 during the packaging process, which may cause increased leakage or even a short circuit between the gate and the source, and affect the performance of the gate bonding pad 29 and the gate.

Exemplarily, in the shielding structure shown in FIG. 9, the second shielding subsection 320 and the third shielding subsection 330 include a section parallel to the extending direction of the first shielding subsection 310 in addition to the section intersecting with the extending direction of the first shielding subsection 310. In this way, the shielding structure has a larger shielding range and a better shielding effect. In other embodiments, a semi-enclosed shielding structure may also be provided with reference to FIG. 9, which is not limited in the embodiments of the present disclosure.

It should be noted that due to the high operating frequency of a semiconductor device, if the shielding structure forms a closed loop, it is easy to generate induction signals and affect the performance of the semiconductor device; therefore, the shielding structure should not be set as a closed-loop structure as much as possible.

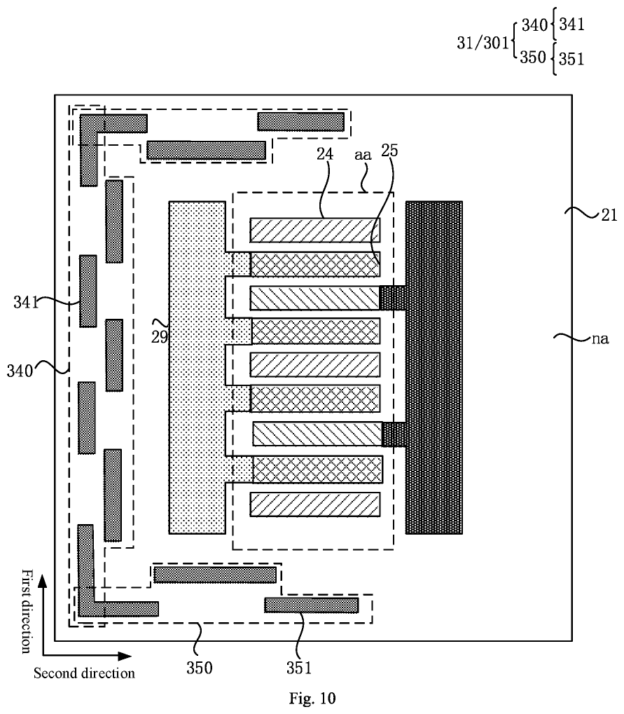

FIG. 10 is a top view schematic diagram illustrating another semiconductor device according to an embodiment of the present disclosure. Referring to FIG. 10, the shielding structure 31 includes a fourth shielding subsection 340 and a fifth shielding subsection 350. The fourth shielding subsection 340 extends along the first direction, the fifth shielding subsection 350 extends along the second direction, and the first direction intersects the second direction and the two both are parallel to the plane where the substrate is located, the fourth shielding subsection 340 includes a plurality of first sub-shielding structures 341, two first sub-shielding structures 341 adjacent along the first direction are arranged staggered in the second direction, and the vertical projections on the first plane overlap, the first plane is parallel to the first direction and perpendicular to the plane where the substrate is located, and/or the fifth shield subsection 350 includes a plurality of second sub-shielding structures 351, two second sub-shielding structures 351 adjacent along the second direction are arranged staggered in the first direction, and the vertical projections on the second plane overlap, the second plane is parallel to the second direction and perpendicular to the plane where the substrate is located.

FIG. 10 takes the shielding structure as a gate shielding structure 301 as an example for illustration. As shown in FIG. 10, the gate shielding structure is composed of a plurality of sub-shielding structures. Exemplarily, FIG. 10 only takes the following as an example for illustration, the fourth shielding subsection 340 includes a plurality of first sub-shielding structures 341, two first sub-shielding structures 341 adjacent along the first direction are arranged staggered in the second direction, and the vertical projections on the first plane overlap, meanwhile, the fifth shielding subsection 350 includes a plurality of second sub-shielding structures 351, two second sub-shielding structures 351 adjacent along the second direction are arranged staggered in the first direction, and the vertical projections on the second plane overlap. In this embodiment, overlapping of the vertical projections of two adjacent sub-shielding structures extending in the same direction in the direction perpendicular to their extension can also play a good shielding role, and those skilled in the art can set them up according to their needs, which is not limited in the embodiment of the present disclosure. It can be understood that when the shielding structure is composed of a plurality of discontinuous sub-shielding structures, each sub-shielding structure is electrically connected to a preset potential.

To sum up, the above embodiments take the shielding structure as a gate shielding structure as an example, and describe the specific arrangement of the shielding structure in detail. On the basis of the above embodiments, since the active region aa includes a plurality of fixed potential structures, for example, the source is a fixed potential structure, and the source potential is 0; for another example, the drain is a fixed potential structure, and the fixed potential of the drain is greater than 0, so the shielding structure may be set to be electrically connected to the fixed potential structure in the active region aa: in this way, a separate external power supply can be avoided, and the structure of the semiconductor device can be kept simple.

The fixed potential structure may include a source, and the shielding structure is electrically connected to the source.

The source potential is 0, and the preset potential on the shielding structure is greater than or equal to 0, so the source is multiplexed into a fixed potential structure, and the shielding structure is set to be directly electrically connected to the source: on the basis of realizing the shielding protection for the bonding pad, the structure of the semiconductor device is ensured to be simple. The embodiment of the present disclosure does not limit the manner of electrically connecting the shielding structure to the source, and those skilled in the art can design it by themselves.

The fixed potential structure may include a drain, and the shielding structure is electrically connected to the drain.

Exemplarily, the drain potential is greater than 0, and the preset potential on the shielding structure is greater than or equal to 0, so the drain is multiplexed as a fixed potential structure, and the shielding structure is directly electrically connected to the drain (not shown in the drawing); on the basis of realizing the shielding protection for the bonding pad, the structure of the semiconductor device is ensured to be simple. The embodiment of the present disclosure does not limit the manner of electrically connecting the shielding structure and the drain, and those skilled in the art can design it by themselves.

It should be noted that when the drain is used as a fixed potential structure and the shielding structure is electrically connected to the drain, the shielding structure can be set as a gate shielding structure instead of a drain shielding structure. Otherwise, when the silver ions in the packaging process move to the drain shielding structure, it will also cause increased leakage or even a short circuit between the drain and the source, resulting in the failure of normal use of the semiconductor device.

It should be noted that when the source or the drain is multiplexed as a fixed potential structure and electrically connected to the shielding structure, either both ends of the shielding structure may be connected to the same source or drain, or may be connected to different sources or drains, which is not limited in this embodiment of the present disclosure.

Based on the same inventive concept, an embodiment of the present disclosure further provides a method of manufacturing a semiconductor device, which is for manufacturing the semiconductor device provided in any of the above embodiments: the manufacturing method may specifically include the following steps:

S101, providing a substrate.

S102, forming a multi-layer semiconductor layer on one side of the substrate.

Exemplarily, the multi-layer semiconductor layer is located on one side of the substrate, and the multi-layer semiconductor layer may specifically be a III-V compound semiconductor material, and 2DEG is formed in the multi-layer semiconductor layer.

S103, forming at least one shielding structure on one side of the substrate, the shielding structure being electrically connected to a preset potential, for forming an electric field or a zero electric field of the active region pointing toward the non-active region.

In the manufacturing method provided by the embodiments of the present disclosure, by forming a shielding structure on one side of the substrate and setting the shielding structure to be electrically connected to a preset potential, an electric field or a zero electric field of the active region pointing toward the non-active region can be formed, which effectively shields silver ions, inhibits their migration to the central area of the front surface of the semiconductor chip, and ensures the normal operation of the semiconductor device.

Based on the above problem of the prior art in FIG. 1, a semiconductor device provided by an embodiment of the present disclosure includes a working region and a scribe region surrounding the working region. The working region includes an active region and a passive region surrounding the active region. The semiconductor device further includes a substrate, a multi-layer semiconductor layer on one side of the substrate, at least one bonding pad located on one side of the multi-layer semiconductor layer away from the substrate, and in the passive region, and at least one shielding structure located on one side of the multi-layer semiconductor layer away from the substrate, the shielding structure being electrically connected to a preset potential, and the preset potential U satisfies U20. With the above technical solution, by setting the shielding structure electrically connected with the preset potential, the silver ions in the patch silver paste are effectively shielded from migrating to the bonding pad during the packaging process, which ensures the stable performance of the bonding pad and the electrode connected to the bonding pad, avoids the short circuit between the bonding pad and the electrode connected to the bonding pad and the source, and ensures the normal operation of the semiconductor device.

The above is the core idea of the present disclosure, and the technical solutions in the embodiments of the present disclosure will be clearly and completely described below in conjunction with the drawings in the embodiments of the present disclosure. Based on the embodiments of the present disclosure, all other embodiments obtained by persons of ordinary skill in the art without making creative efforts belong to the protection scope of the present disclosure.

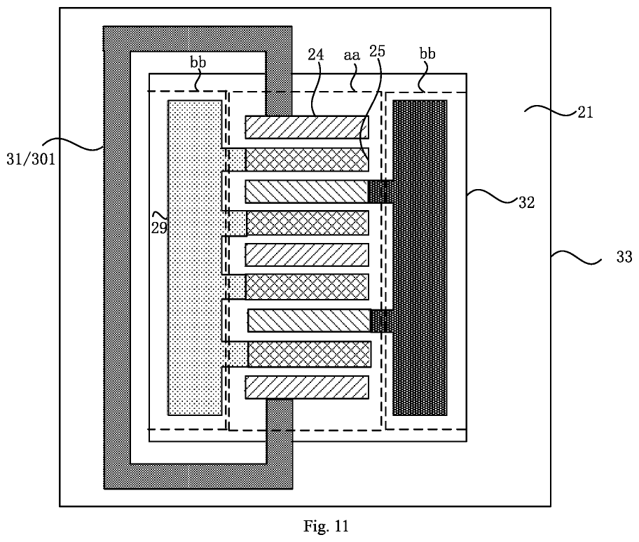

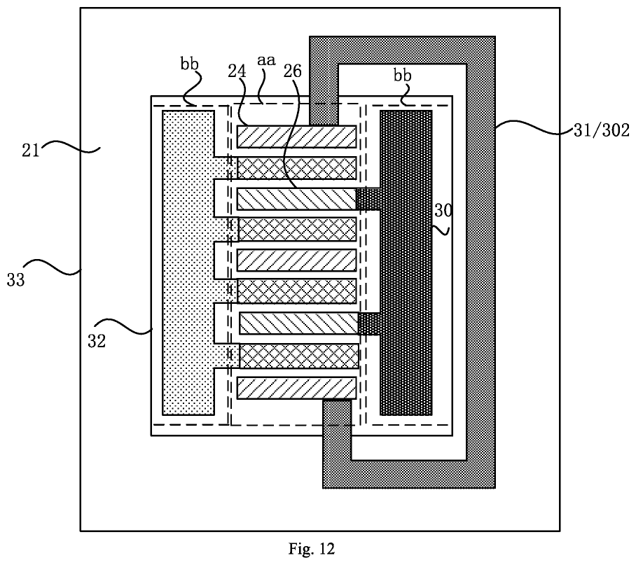

FIG. 11 is a top view schematic diagram illustrating a semiconductor device according to an embodiment of the present disclosure, and FIG. 12 is a top view schematic diagram illustrating another semiconductor device according to an embodiment of the present disclosure. As shown in FIG. 11 and FIG. 12, the semiconductor device provided by the embodiment of the present disclosure includes a working region 32 and a scribe region 33 surrounding the working region 32. The working region 32 includes an active region aa and a passive region bb surrounding the active region aa.

The semiconductor device further includes a substrate 21, a multi-layer semiconductor layer located on one side of the substrate (not shown in the drawing), at least one bonding pad located on one side of the multi-layer semiconductor layer away from the substrate 21, and located in the passive region bb, and at least one shielding structure 31 located on one side of the multi-layer semiconductor layer 22 away from the substrate 21, the shielding structure 31 being for shielding and protecting the bonding pad, wherein the shielding structure is electrically connected to the preset potential, and the preset potential U satisfies U≥0.

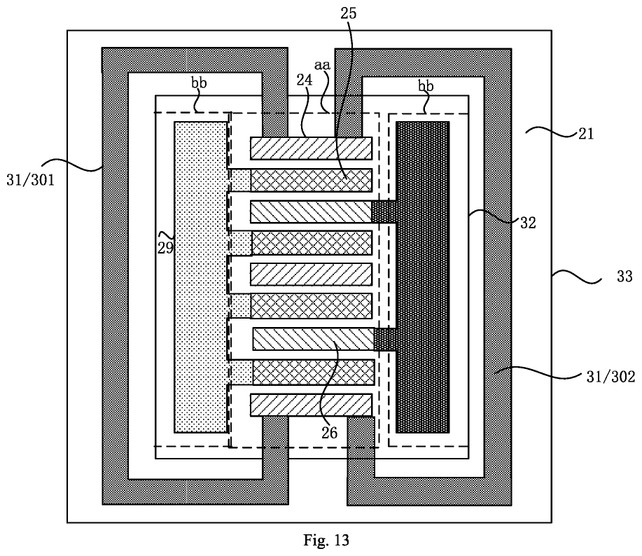

The bonding pad may be a gate bonding pad located in the passive region bb, correspondingly, the shielding structure may be a gate shielding structure, and/or the bonding pad is a drain bonding pad, and correspondingly, the shielding structure is a drain shielding structure, which is not specifically limited in this embodiment of the present disclosure. Wherein, FIG. 11 takes the bonding pad as the gate bonding pad 29, and the shielding structure 31 as the gate shielding structure 301 as an example for illustration, and FIG. 12 takes the bonding pad as the drain bonding pad 30, and the shielding structure 31 as the drain shielding structure 302 as an example for illustration; and FIG. 13 takes the bonding pads including a gate bonding pad 29 and a drain bonding pad 30, and the shielding structure 31 including a gate shielding structure 301 and a drain shielding structure 302 as an example for illustration.

Further, the shielding structure 31 is electrically connected to the preset potential, and the preset potential U satisfies U>0. The bonding pad may be shielded and protected through the shielding structure 31, effectively shielding the silver ions in the patch silver paste from migrating to the bonding pad, ensuring stable performance of the bonding pad and electrodes connected to the bonding pad, avoiding short circuit between the bonding pad and the electrode connected to the bonding pad and the source, and ensuring the normal operation of the semiconductor device.

Further, the preset potential may be a positive potential or a zero potential introduced by an external power supply, or a fixed potential structure directly connected to the active region aa, which is not limited in this embodiment of the present disclosure.

To sum up, in the semiconductor device provided by the embodiment of the present disclosure, by adding a shielding structure and electrically connecting the shielding structure to a preset potential, the bonding pad can be effectively shielded and protected, and the silver ions in the patch silver paste during the packaging process can be effectively shielded from migrating to the bonding pad, ensuring stable performance of the bonding pad and electrodes connected to the bonding pad, avoiding short circuit between the bonding pad and the electrode connected to the bonding pad and the source, and ensuring the normal operation of the semiconductor device.

The technical solutions of the embodiments of the present disclosure will be described in detail below in terms of the specific arrangement of the two shielding structures.

Continuing referring to FIG. 11, the semiconductor device further includes a gate 25 located on one side of the multi-layer semiconductor layer away from the substrate 21, and located in the active region aa. At least one bonding pad includes a gate bonding pad 29, and the gate bonding pad 29 is electrically connected to the gate 25, and at least one shielding structure 31 includes a gate shielding structure 301, and the gate shielding structure 301 is for shielding and protecting the bonding pad of the gate 25.

As shown in FIG. 11, the semiconductor device further includes a gate 25, the gate 25 is electrically connected to the gate bonding pad 29, and the gate shielding structure 301 is for shielding and protecting the gate bonding pad 29 and the gate 25, so as to prevent the silver ions in the patch silver paste from migrating to the gate bonding pad 29 during the packaging process, which may cause a short circuit between the gate 25 and the source 24, affect the performance of the gate bonding pad 29 and the gate 25, and further affect the performance of the semiconductor device, resulting in the failure of normal use of the semiconductor device.

Continuing to refer to FIG. 13, the semiconductor device further includes a drain 26 located on one side of the multi-layer semiconductor layer away from the substrate 21, and located in the active region aa. At least one bonding pad further includes a drain bonding pad 30, and the drain bonding pad 30 is connected to the drain 26, and at least one shielding structure 31 includes a drain shielding structure 302 for shielding and protecting the drain bonding pad 30.

As shown in FIG. 13, the semiconductor device further includes a gate 25 and a drain 26, and the gate 25 is electrically connected to a gate bonding pad 29. The gate shielding structure 301 is for shielding and protecting the gate bonding pad 29 and the gate 25, so as to prevent the silver ions in the patch silver paste from migrating to the gate bonding pad 29 during the packaging process, which may cause a short circuit between the gate 25 and the source 24, and affect the performance of the gate bonding pad 29 and the gate 25. The drain 26 is electrically connected to the drain bonding pad 30, and the drain shielding structure 302 is for shielding and protecting the drain bonding pad 30 and the drain 26 to prevent silver ions in the patch silver paste from migrating to the drain bonding pad 30 during the packaging process, which may cause a short circuit between the drain 26 and the source 24, and affect the performance of the drain bonding pad 30 and the drain 26, and further affect the performance of the semiconductor device, and result in the failure of normal use of the semiconductor device.

On the basis of the above embodiments, since the active region aa includes a plurality of fixed potential structures, for example, the source is a fixed potential structure, and the source potential is 0; for another example, the drain is a fixed potential structure, and the fixed potential of the drain is greater than 0, so the shielding structure can be set to be electrically connected to the fixed potential structure in the active region aa: in this way, a separate external power supply can be avoided, and the structure of the semiconductor device can be kept simple.

Continuing referring to FIG. 11, FIG. 12, and FIG. 13, the fixed potential structure includes a source 24, and the shielding structure 31 is electrically connected to the source 24.

The potential of the source 24 is 0, and the preset potential on the shielding structure is greater than or equal to 0, so the source 24 is multiplexed as a fixed potential structure, and the shielding structure 31 is set to be directly electrically connected to the source 24. On the basis of realizing the shielding protection for the bonding pad, the structure of the semiconductor device is ensured to be simple. As shown in FIG. 11, FIG. 12, and FIG. 13, the shielding structure 31 here may include a gate shielding structure 301 and/or a drain shielding structure 302.

The shielding structure may include a gate shielding structure. The fixed potential structure includes a drain, and the gate shielding structure is electrically connected to the drain.

Exemplarily, the potential of the drain is greater than 0, the preset potential on the shielding structure is greater than or equal to 0, so the drain is multiplexed into a fixed potential structure, and the shielding structure is set to be directly electrically connected to the drain (not shown in the drawing); on the basis of realizing the shielding protection for the bonding pad, the structure of the semiconductor device is ensured to be simple. It should be noted that when the drain is used as a fixed potential structure and the shielding structure is electrically connected to the drain, the shielding structure can be set as a gate shielding structure instead of a drain shielding structure: otherwise, when the silver ions in the packaging process move to the drain shielding structure, it will also cause a short circuit between the drain and the source, and result in the failure of normal use of the semiconductor device.

It should be noted that when the source or the drain is multiplexed as a fixed potential structure and electrically connected to the shielding structure, both ends of the shielding structure may be connected to the same source or drain, or may be connected to different sources or drains, which is not limited in this embodiment of the present disclosure.

In the following, the source is multiplexed as a fixed potential structure, the shielding structure is electrically connected to different sources, and the shielding structure is a gate shielding structure as an example for illustration.

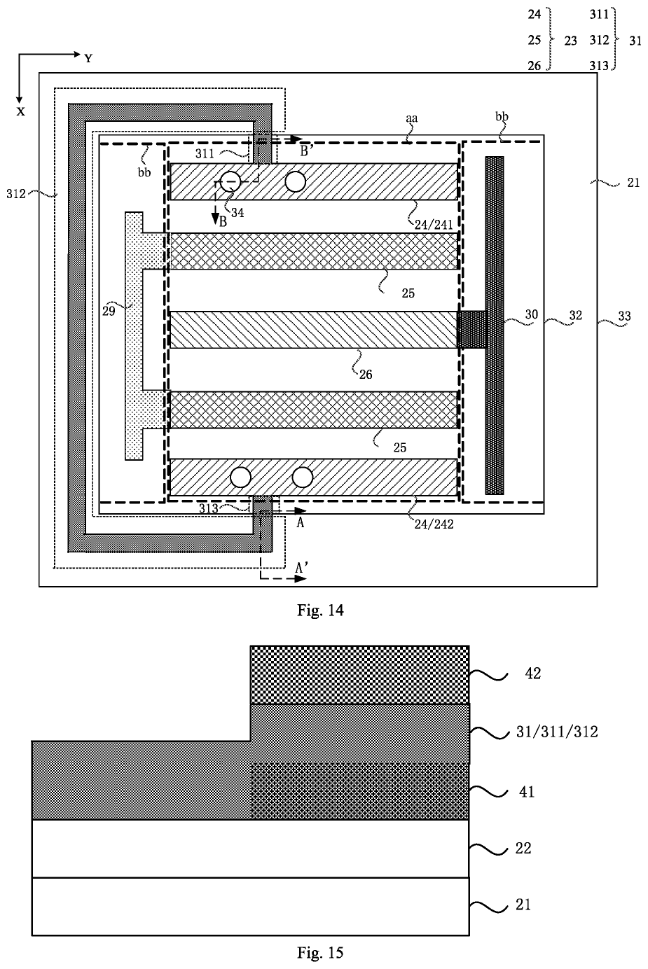

FIG. 14 is a top view schematic diagram illustrating another semiconductor device according to an embodiment of the present disclosure. As shown in FIG. 14, the source 24 may include a first source 241 and an Nth source arranged along a first direction, and the first direction is parallel to the plane where the substrate 21 is located. The first source 241 is located at the first end of the active region aa, the Nth source is located at the second end of the active region aa, and the first end and the second end are oppositely arranged along the first direction, and the shielding structure 31 is electrically connected to the first source and the Nth source respectively, and the gate bonding pad 29 is located in an interval defined by the shielding structure and the active region aa.

Exemplarily, FIG. 14 takes N equal to 2 as an example for illustration. As shown in FIG. 14, the first source 241, the gate 25, and the drain 26 extend along the second direction (the Y direction shown in the drawing) in the active region aa, and the extension length does not exceed the range of the active region aa, at the same time, the first source 241, the gate 25, and the drain 26 are arranged in the active region aa along the first direction (the X direction shown in the drawing), and the length of the arrangement does not exceed the range of the active region aa. The first direction is parallel to the direction in which the first source 241 points toward the drain 26, and the second direction intersects the first direction and the two both are parallel to the plane where the substrate 21 is located. As shown in FIG. 14, one end of the shielding structure 31 is electrically connected to the first source 241, and the other end is electrically connected to the second source 242. The shielding structure 31 has a semi-circular structure, the gate bonding pad 29 is located in the interval defined by the shielding structure 31 and the active region aa, and the shielding structure 31 completely surrounds the gate bonding pad 29. In this way, the electrical connection between the shielding structure 31 and the source 24 effectively shields the silver ions in the patch silver paste migrating to the grid under the action of an electric field, and there is no need to separately set up a power supply to be electrically connected to the shielding structure 31, to reduce complex wiring and reduce costs.

FIG. 15 is a cross-sectional schematic diagram illustrating the semiconductor device provided in FIG. 14 along the section line A-A′. As shown in FIG. 14 and FIG. 15, the source 24 is electrically connected to the source back electrode (not shown in the drawing) through the via hole 34;
the overlapping area of the vertical projection of the shielding structure 31 on the plane where the substrate is located and the vertical projection of the via hole 34 on the plane where the substrate is located is S1; and
the vertical projected area of the via hole 34 on the plane where the substrate is located is S2;
where S1<S2/4.

Exemplarily, the source 24 is electrically connected to the source back electrode through the via hole 34, and the shape of the via hole 34 may be circular, oval, semicircular, etc., which is not limited in this embodiment of the present disclosure. Considering that the shielding structure 31 needs to be effectively electrically connected to the source 24, avoiding the connection between the shielding structure 31 and the via hole 34 will cause a virtual connection of the shielding structure 31, and the shielding structure 31 cannot achieve the shielding effect: therefore, it is set that the overlapping area S1 of the vertical projection of the shielding structure 31 on the plane where the substrate 21 is located and the vertical projection of the via hole 34 on the plane where the substrate 21 is located is less than a quarter of the vertical projected area S2 of the via hole 34 on the plane where the substrate 21 is located, that is, S1<S2/4, to ensure the effective electrical connection between the shielding structure 31 and the source 24 and realize the shielding effect of the shielding structure 31.

The vertical projection of the shielding structure 31 on the plane where the substrate 21 is located does not overlap with the vertical projection of the via hole 34 on the plane where the substrate 21 is located.

Exemplarily, as shown in FIG. 14, the vertical projection of the shielding structure 31 on the plane where the substrate 21 is located does not overlap with the vertical projection of the via hole 34 on the plane where the substrate 21 is located, at the time, the shape and area of the via hole 34 are not limited, and both can realize an effective electrical connection between the shielding structure 31 and the source 24 to achieve an optimal shielding effect, thereby achieving stable performance of the semiconductor device.

On the basis of the above embodiments, the shielding structure 31 can correspond to a variety of different installation positions, and in different installation positions, the film layer settings of the semiconductor device can be different: the following describes in detail with two feasible implementation manners.

As a feasible implementation manner, continuing referring to FIG. 14, the shielding structure 31 includes a first shielding subsection 311, a second shielding subsection 312, and a third shielding subsection 313, and the second shielding subsection 312 is respectively connected to the first shielding subsection 311 and the third shielding subsection 313. The second shielding subsection 312 is located in the scribe region 33, the first shielding subsection 311 is located in the working region 32 and is electrically connected to the first source 241, and the third shielding subsection 313 is located in the working region 32 and is electrically connected to the second source 242.

Specifically, the working region 32 may be understood as the region where the semiconductor device works, which includes the active region aa and the passive region bb. The active region aa may be understood as the region where two-dimensional electron gas, electrons or holes exist, and its working state and characteristics are affected by external circuits, which is the active working region of the semiconductor device. The passive region bb may be understood as the region outside the active region aa that participates in the operation of the device, but the working state is not affected by external circuits. The scribe region 33 refers to the region where a semiconductor device is diced and cut to form a plurality of independent semiconductor devices. The second shielding subsection 312 is located in the scribe region 33, that is, most of the shielding structure 31 is located in the scribe region 33, under the premise of shielding silver ions, it is ensured that the setting of the shielding structure 31 will not affect the normal operation of the semiconductor device, and ensure the stable performance of the semiconductor device.

On the basis of the above embodiments, continuing referring to FIG. 14 and FIG. 15, the semiconductor device may further include a first dielectric layer 41 located on one side of the multi-layer semiconductor layer 22 away from the substrate 21, and located in the passive region bb, both the first shielding subsection 311 and the third shielding subsection 313 are located on one side of the first dielectric layer 41 away from the substrate 21, along the direction perpendicular to the substrate 21, the thickness of the shielding structure 31 is greater than that of the first dielectric layer 41, so that the first shielding subsection 311 and the third shielding subsection 313 are electrically connected to the second shielding subsection 312.

Exemplarily, the semiconductor device may further include a first dielectric layer 41 located in the passive region bb, and the first dielectric layer 41 may, for example, be an insulating layer or a waterproof layer to protect the semiconductor structure located in the passive region, moreover, since the scribe region 33 needs to be scribed and cut later, in order to ensure a simple scribing process, the first dielectric layer 41 is generally not provided in the scribe region 33, in this way, there is a gap between the disposition surface of the second shielding subsection 312 located in the scribe region 33 and the disposition surfaces of the first shielding subsection 311 and the second shielding subsection 313. In order to ensure that the connection between the second shielding subsection 312 and the first shielding subsection 311 as well as the third shielding subsection 313 is maintained, it needs to be set along the direction perpendicular to the substrate 21, the thickness of the shielding structure 31 is greater than that of the first dielectric layer 41, in this way, the position where the second shielding subsection 312 is connected to the first shielding subsection 311 as well as the third shielding subsection 313 will not be disconnected, which ensures the integrity of the shielding structure 31 and realizes shielding protection for the gate bonding pad.

Wherein, the material of the first dielectric layer 41 may be SiN, SiO and other dielectric materials.

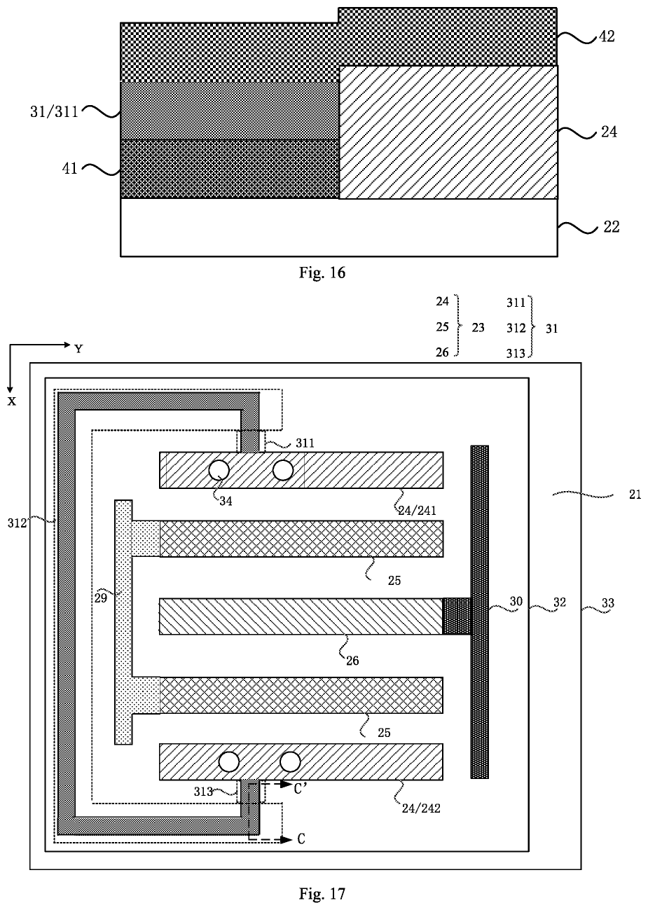

FIG. 16 is a cross-sectional schematic diagram illustrating the semiconductor device provided in FIG. 14 along the section line B-B′. As shown in FIG. 14 and FIG. 16, the semiconductor device further includes a first dielectric layer 41 located on one side of the multi-layer semiconductor layer 22 away from the substrate 21, and located in the passive region bb, along the direction perpendicular to the substrate 21, the thickness of the source 24 is greater than that of the first dielectric layer 41, so that the first shielding subsection 311 and the third shielding subsection 313 are both electrically connected to the source 24.

Exemplarily, the semiconductor device may further include a first dielectric layer 41 located in the passive region bb, and the first dielectric layer 41 may, for example, be an insulating layer or a waterproof layer to protect the semiconductor structure located in the passive region bb, moreover, the source 24 needs to form an ohmic contact with the multi-layer semiconductor layer 22, so the first dielectric layer 41 is generally not provided between the source 24 and the multi-layer semiconductor layer 22.

Further, the first shielding subsection 311 and the third shielding subsection 313 need to be electrically connected to the source 24 and ensure that the shielding structure 31 is connected to a fixed potential, so the thickness of the source 24 and the thickness of the first dielectric layer 41 need to be reasonably set to ensure that the first shielding subsection 311 and the third shielding subsection 313 can be electrically connected to the source 24. Specifically, along the direction perpendicular to the substrate 21, the thickness of the source 24 may be greater than that of the first dielectric layer 41, so that both the first shielding subsection 311 and the third shielding subsection 313 are electrically connected to the source 24. Otherwise, an effective connection cannot be formed between the source 24 and the shielding structure 31, and the shielding structure 31 will also be floating, and the electric field shielding effect will not be achieved, and the silver ions in the patch silver paste will be transferred to the gate bonding pad 29, causing potentials of the gate 25 and the source 24 to be the same, and a short circuit will occur between the gate 25 and the source 24.

Continuing referring to FIG. 16, the semiconductor device further includes a second dielectric layer 42 located in the working region 32, the second dielectric layer 42 covers the first shielding subsection 311, the third shielding subsection 313 and the source 24, and in a direction perpendicular to the substrate 21, the sum of the thicknesses of the first dielectric layer 41, the first shielding subsection 311 and the second dielectric layer 42 is greater than the thickness of the source 24, so that the second dielectric layer 42 on one side of the first shielding subsection 311 away from the substrate 21 is connected to the second dielectric layer 42 on one side of the source 24 away from the substrate.

Exemplarily, the semiconductor device provided by the embodiment of the present disclosure may further include a second dielectric layer 42, and the second dielectric layer 42 covers the working region 32 and can protect the working region 32. Specifically, the second dielectric layer 42 covers the first shielding subsection 311, the third shielding subsection 313 and the source 24. Since the upper surfaces of the first shielding subsection 311 and the third shielding subsection 313 located in the passive region bb may not be flush with the upper surface of the source 24, that is, there is a gap between the first shielding subsection 311 as well as the third shielding subsection 313 and the source 24, in order to prevent the second dielectric layer 42 from breaking in the region where the first shielding subsection 311 and the third shielding subsection 313 are connected to the source 24, the relationship between the sum of the thicknesses of the first dielectric layer 41, the first shielding structure 313 or the third shielding structure 313 and the second dielectric layer 41 and the thickness of the source 24 needs to be reasonably set. Specifically, in a direction perpendicular to the substrate 21, the sum of the thicknesses of the first dielectric layer 41, the first shielding subsection 311 and the second dielectric layer 42 is greater than the thickness of the source 24. Otherwise, the second dielectric layer 42 located in the passive region bb and the second dielectric layer 42 located in the active region aa are broken, so that the second dielectric layer 42 cannot protect the entire working region 32, which may cause water and oxygen to enter the semiconductor device, causing the metal layer of the source 24 to oxidize or fail, resulting in a risk of reliability failure and directly affecting the performance of the semiconductor device.

Wherein, the material of the second dielectric layer 42 may be SiN, SiO and other dielectric materials.

As a feasible implementation manner, FIG. 17 is a top view schematic diagram illustrating another semiconductor device according to an embodiment of the present disclosure. As shown in FIG. 17, the shielding structure 31 may include a first shielding subsection 311, a second shielding subsection 312, and a third shielding subsection 313, and the second shielding subsection 312 is respectively connected to the first shielding subsection 311 and the third shielding subsection 313, and the first shielding subsection 311, the second shielding subsection 312, and the third shielding subsection 313 are all located in the working region 32, the first shielding subsection 311 is electrically connected to the first source 241, and the third shielding subsection 313 is electrically connected to the second source 242.

Exemplarily, the first shielding subsection 311, the second shielding subsection 312 and the third shielding subsection 313 are all located in the working region 32 instead of being arranged in the scribe region 33. In this way, the semiconductor device including the shielding structure 31 is arranged compactly, and the semiconductor device has a small volume, which is beneficial to realize the miniaturization design of the semiconductor device.

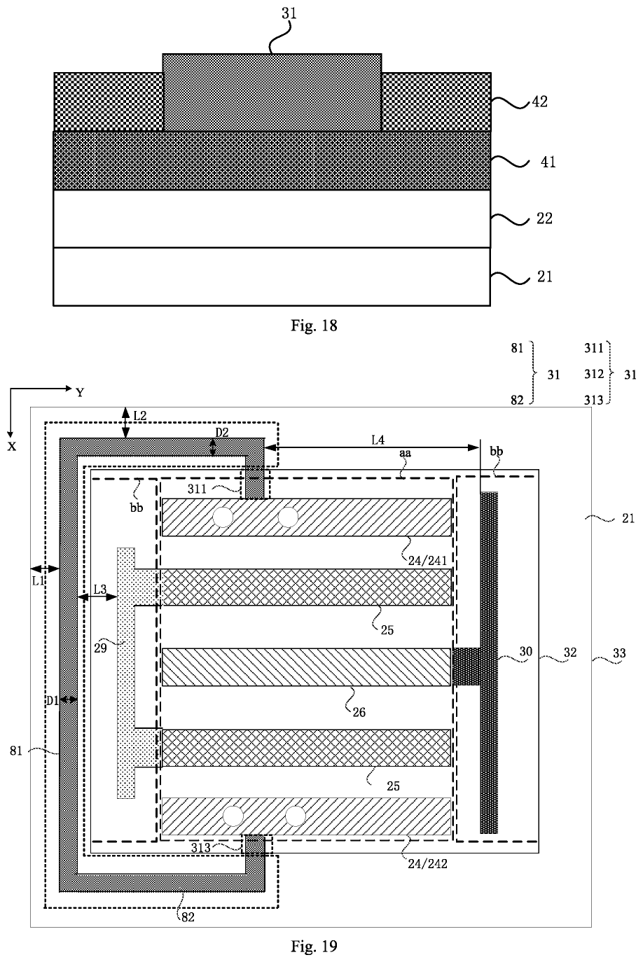

On the basis of the above embodiments, FIG. 18 is a cross-sectional schematic diagram illustrating the semiconductor device provided in FIG. 17 along the section line C-C′. As shown in FIG. 18, the semiconductor device further includes at least one dielectric layer located on one side of the multi-layer semiconductor layer 22 away from the substrate 21, and located in the passive region bb, at least one dielectric layer includes a first surface on one side of the multi-layer semiconductor layer 22 away from the substrate 21, the shielding structure 31 includes a second surface located on one side of the multi-layer semiconductor layer 22 away from the substrate 21, and along the direction perpendicular to the substrate 21, the second surface is located on one side of the first surface away from the substrate 21.

Exemplarily, as shown in FIG. 18, at least one dielectric layer may include, for example, a first dielectric layer 41 and a second dielectric layer 42. The solid layer 41 may, for example, be used as an insulating layer or a waterproof layer to protect the semiconductor structure located in the passive region bb. The second dielectric layer 42 may protect the entire working region 32 to prevent water and oxygen from entering into the semiconductor device and affecting the performance of the semiconductor device. When the dielectric layer includes a plurality of dielectric layers, the first surface may be understood as the surface on one side of the uppermost dielectric layer away from the substrate, taking FIG. 18 as an example, the first surface is the surface of the second dielectric layer 42 away from the substrate 21. Further, the shielding structure 31 includes a second surface on one side of the multi-layer semiconductor layer 22 away from the substrate 21, in the direction perpendicular to the substrate 21, the second surface is located on one side of the first surface away from the substrate 21, that is, the shielding structure 31 protrudes more than the dielectric layer, from the perspective of electric field lines, it may be understood that the electric field line radiation area of the shielding structure 31 is wider, so the shielding structure 31 may shield more silver ions, and the shielding structure 31 has a good shielding effect.

Further, as shown in FIG. 18, when both the shielding structure 31 and the second dielectric layer 42 are located on one side of the first dielectric layer 41 away from the substrate 21, the surface of the shielding structure 31 away from the substrate 21 is further away from the substrate 21 than the surface of the second dielectric layer 42 away from the substrate 21. It can be understood that the thickness of the shielding structure 31 is greater than that of the second dielectric layer 42.

The source 24 may include a multi-layer source metal layer, and the shielding structure 31 may include a one-layer shielding metal layer, and the shielding metal layer and one side of the multi-layer source metal layer are provided on the same layer and made of the same material, or the shielding structure 31 includes a multi-layer shielding metal layer, and the multi-layer shielding metal layer corresponds to the multi-layer source metal layer one by one, and the shielding metal layer and the source metal layer set correspondingly are provided on the same layer and made of the same material.

Wherein, the source 24 includes a multi-layer source metal layer, and the material composition of the multi-layer source metal layer may include but not limited to Ti, Al, Ni, Au, and other metals. The shielding structure 31 may include one or more shielding metal layers, when the shielding structure 31 includes a one-layer shielding metal layer, the shielding metal layer may be provided in the same layer and made of the same material as one of the multi-layer source metal layers, and can be prepared in the same process, so that the manufacturing process of the shielding structure 31 is simple: when the shielding structure 31 includes a multi-layer shielding metal layer, the multi-layer shielding metal layer may correspond to the multi-layer source metal layer one by one, and the shielding metal layer and the source metal layer set correspondingly are provided on the same layer and made of the same material, and they can be prepared in the same process, so that the manufacturing process of the shielding structure 31 is simple.

On the basis of the above embodiments, the multi-layer semiconductor layer 22 of the semiconductor device 20 provided by the embodiment of the present disclosure may specifically include a nucleation layer located on the substrate 21, a buffer layer located on one side of the nucleation layer away from the substrate 21, a channel layer located on one side of the buffer layer away from the nucleation layer; and a barrier layer located on one side of the channel layer away from the buffer layer, wherein the barrier layer and the channel layer form a heterojunction structure, and a 2DEG (not shown in the drawing) is formed at the interface of the heterojunction.

Based on the same inventive concept, an embodiment of the present disclosure further provides a method of manufacturing a semiconductor device. The method of manufacturing a semiconductor device provided in the embodiment of the present disclosure may include:

S201, providing a substrate.

Exemplarily, the material of the substrate may be Si, SiC, gallium nitride or sapphire, or other materials suitable for growing gallium nitride. The manufacturing method of the substrate may be atmospheric pressure chemical vapor deposition, sub-atmospheric chemical vapor deposition, metal organic compound vapor deposition, low pressure chemical vapor deposition, high density plasma chemical vapor deposition, ultra-high vacuum chemical vapor deposition, plasma enhanced chemical vapor deposition, catalytic chemical vapor deposition, mixture physical chemical vapor deposition, rapid thermal chemical vapor deposition, vapor phase epitaxy, pulsed laser deposition, atomic layer epitaxy, molecular beam epitaxy, sputtering or evaporation.

S202, forming a multi-layer semiconductor layer on one side of the substrate.

Exemplarily, the multi-layer semiconductor layer is located on one side of the substrate, and the multi-layer semiconductor layer may specifically be a III-V compound semiconductor material, and 2DEG is formed in the multi-layer semiconductor layer.

S203, forming at least one bonding pad on one side of the multi-layer semiconductor layer away from the substrate, and in the passive region.

S204, forming at least one shielding structure on one side of the multi-layer semiconductor layer away from the substrate, where the shielding structure is for shielding and protecting the bonding pad. The shielding structure is electrically connected to a preset potential, and the preset potential U satisfies U≥0.

By forming a shielding structure on one side of the multi-layer semiconductor layer away from the substrate, and setting the shielding structure to be electrically connected to a preset potential, silver ions in the patch silver paste are effectively shielded from migrating to the bonding pad during the packaging process, ensuring the stable performance of the bonding pad and the electrodes connected to the bonding pad, avoiding the short circuit between the bonding pad as well as the electrode connected to the bonding pad and the source, and ensuring the normal operation of the semiconductor device.

On the basis of the above embodiments, the source may include a multi-layer source metal layer, the shielding structure may include a one-layer or a multi-layer source metal layer, and the shielding structure and the source may be formed in the same manufacturing process, ensuring a simple manufacturing process of the semiconductor device.

Based on the above problem of the prior art in FIG. 1, a semiconductor device provided by an embodiment of the present disclosure includes a working region and a scribe region surrounding the working region, the working region includes an active region and a passive region surrounding the active region, the semiconductor device further includes a substrate, a multi-layer semiconductor layer on one side of the substrate, a gate on one side of the multi-layer semiconductor layer away from the substrate, and in the active region, at least one bonding pad located on one side of the multi-layer semiconductor layer away from the substrate, and located in the passive region, wherein the bonding pad includes at least a gate bonding pad, and the gate bonding pad is electrically connected to the gate, and at least one shielding structure located on one side of the multi-layer semiconductor layer away from the substrate, the shielding structure includes a gate shielding structure, and the gate shielding structure is for shielding and protecting the gate bonding pad. With the above technical solution, by setting the shielding structure, the silver ions in the patch silver paste are effectively shielded from migrating to the bonding pad during the packaging process, ensuring the stable performance of the bonding pad and the electrode connected to the bonding pad, avoiding the short circuit between the bonding pad as well as the electrode connected to the bonding pad and the source, and ensuring the normal operation of the semiconductor device.

The above is the core idea of the disclosure, and the technical solutions in the embodiments of the present disclosure will be clearly and completely described below in conjunction with the drawings in the embodiments of the present disclosure. Based on the embodiments of the present disclosure, all other embodiments obtained by persons of ordinary skill in the art without making creative efforts belong to the protection scope of the present disclosure.

FIG. 11 is a top view schematic diagram illustrating a semiconductor device according to an embodiment of the present disclosure, and FIG. 13 is a top view schematic diagram illustrating another semiconductor device according to an embodiment of the present disclosure. As shown in FIG. 11 and FIG. 13, the semiconductor device provided by the embodiment of the present disclosure includes a working region 32 and a scribe region 33 surrounding the working region 32. The working region 32 includes an active region aa and a passive region bb surrounding the active region aa.

The semiconductor device further includes a substrate 21, a multi-layer semiconductor layer (not shown in the drawing) located on one side of the substrate 21, a gate 25 located on one side of the multi-layer semiconductor layer away from the substrate 21, and located in the active region aa, at least one bonding pad located on one side of the multi-layer semiconductor layer away from the substrate 21, and located in the passive region bb, wherein the bonding pad includes at least a gate bonding pad 29, and the gate bonding pad 29 is electrically connected to the gate 25, and at least one shielding structure 31 located on one side of the multi-layer semiconductor layer away from the substrate 21, wherein the shielding structure 31 includes a gate shielding structure 301, and the gate shielding structure 301 is for shielding and protecting the gate bonding pad 29.

The material of the substrate 21 may be formed of one or more materials among silicon, sapphire, silicon carbide, gallium arsenide, gallium nitride, diamond, etc., and may further be other materials suitable for growing gallium nitride.

The multi-layer semiconductor layer is located on one side of the substrate 21, and specifically, the multi-layer semiconductor layer may be a III-V compound semiconductor material, for example, may be formed of one or more of gallium arsenide, aluminum gallium arsenide, gallium nitride, aluminum gallium nitride or indium gallium nitride.

The bonding pad may be the gate bonding pad 29 located in the passive region bb, the shielding structure 31 may be a gate shielding structure 301, and the gate shielding structure 301 is for shielding and protecting the gate bonding pad 29, during the packaging process, the gate shielding structure 301 can effectively shield the silver ions in the patch silver paste from migrating to the gate bonding pad 29, which can ensure that the performance of the gate bonding pad 29 and the gate 25 electrically connected to the gate bonding pad 29 is stable, and no short circuit will occur between the source 24, ensure that the potential of the gate 25 and the source 24 of the semiconductor device is normal, and ensure the normal operation of the semiconductor device.

To sum up, with the semiconductor device provided by the embodiment of the present disclosure, by adding a gate shielding structure, the gate bonding pad can be effectively shielded and protected by the gate shielding structure, which can effectively shield the silver ions in the patch silver paste from migrating to the gate bonding pad during the packaging process, ensure the stable performance of the gate bonding pad and the electrode connected to the gate bonding pad, avoid the short circuit between the gate bonding pad and the electrode connected to the gate bonding pad and the source, and ensure the normal operation of the semiconductor device.

FIG. 13 is a top view schematic diagram illustrating another semiconductor device according to an embodiment of the present disclosure. As shown in FIG. 13, the semiconductor device further may include a drain 26 located on one side of the multi-layer semiconductor layer away from the substrate 21, and located in the active region aa. The bonding pad further includes a drain bonding pad 30, and the drain bonding pad 30 is electrically connected to the drain 26, and the shielding structure further includes a drain shielding structure 302 for shielding and protecting the drain bonding pad 30.

As shown in FIG. 13, the semiconductor device includes a drain 26, and the drain 26 is electrically connected to a drain bonding pad 30. The drain shielding structure 302 is for shielding and protecting the drain bonding pad 30 and the drain 26 to prevent silver ions in the patch silver paste from migrating to the drain bonding pad 30 during the packaging process, which may cause a short circuit between the drain 26 and the source 24, affect the performance of the drain bonding pad 30 and the drain 26, and further affect the performance of the semiconductor device, and result in the failure of normal use of the semiconductor device.

The shielding structure is electrically connected to a preset potential, and the preset potential U satisfies U≥0.

Further, the potential on the shielding structure 31 may be a potential greater than or equal to 0; the bonding pad can be shielded and protected through the shielding structure 31, effectively shielding the silver ions in the patch silver paste from migrating to the bonding pad, ensuring stable performance of the bonding pad and electrodes connected to the bonding pad, avoiding short circuit between the bonding pad and the electrode connected to the bonding pad and the source, and ensuring the normal operation of the semiconductor device.

Further, the preset potential may be a positive potential or zero potential introduced by an external power supply, or a fixed potential structure directly connected to the active region aa, which is not limited in the embodiment of the present disclosure.

On the basis of the above embodiment, since the active region aa includes a plurality of fixed potential structures, for example, the source is a fixed potential structure, and the source potential is 0; for another example, the drain is a fixed potential structure, and the fixed potential of the drain is greater than 0; therefore, the shielding structure can be set to be electrically connected to the fixed potential structure in the active region aa, so that a separate external power supply can be avoided, and the structure of the semiconductor device can be kept simple.

The fixed potential structure may include a source 24, and the shielding structure 31 is electrically connected to the source 24.

The potential of the source 24 is 0, and the preset potential on the shielding structure is greater than or equal to 0, so the source 24 is multiplexed as a fixed potential structure, and the shielding structure 31 is set to be directly electrically connected to the source 24: on the basis of realizing the shielding protection for the bonding pad, the structure of the semiconductor device is ensured to be simple. As shown in FIG. 11 and FIG. 13, the shielding structure 31 here may include a gate shielding structure 301 and/or a drain shielding structure 302.

The fixed potential structure may include a drain 26, and the gate shielding structure 301 is electrically connected to the drain 26.

Exemplarily, the potential of the drain is greater than 0, and the preset potential on the shielding structure is greater than or equal to 0, so the drain is multiplexed into a fixed potential structure, and the shielding structure is set to be directly electrically connected to the drain (not shown in the drawing); on the basis of realizing the shielding protection for the bonding pad, the structure of the semiconductor device is ensured to be simple. It should be noted that when the drain is used as a fixed potential structure and the shielding structure is electrically connected to the drain, the shielding structure can be set as a gate shielding structure instead of a drain shielding structure: otherwise, when the silver ions in the packaging process move to the drain shielding structure, it will also cause a short circuit between the drain and the source, and result in the failure of normal use of the semiconductor device.

It should be noted that when the source or the drain is multiplexed as a fixed potential structure and electrically connected to the shielding structure, both ends of the shielding structure may be connected to the same source or drain, or may be connected to different sources or drains, which is not limited in this embodiment of the present disclosure. In the following, it will be described as an example that the source is multiplexed as a fixed potential structure, the shielding structure is electrically connected to different sources, and the shielding structure is a gate shielding structure.

FIG. 19 is a top view schematic diagram illustrating another semiconductor device according to an embodiment of the present disclosure. As shown in FIG. 19, the source 24 may include a first source 241 and an Nth source arranged along a first direction, and the first direction is parallel to the plane where the substrate is located. The first source is located at the first end of the active region aa, the Nth source is located at the second end of the active region aa, and the first end and the second end are oppositely arranged along the first direction, and the shielding structure 31 is electrically connected to the first source 241 and the Nth source respectively, and the gate bonding pad 29 is located in an interval defined by the shielding structure and the active region aa.

Exemplarily, FIG. 19 takes N equal to 2 as an example to illustrate that the first source 241, the gate 25 and the drain 26 extend in the active region aa along the second direction (the Y direction as shown in the drawing), and the extension length does not exceed the range of the active region aa. At the same time, the first source 241, the gate 25, and the drain 26 are arranged in the active region aa along the first direction (the X direction as shown in the drawing), and the length of the arrangement does not exceed the range of the active region aa. The first direction is parallel to the direction in which the first source 241 points toward the drain 26, and the second direction intersects the first direction and the two are parallel to the plane where the substrate 21 is located. As shown in FIG. 19, one end of the shielding structure 31 is electrically connected to the first source 241, and the other end is electrically connected to the second source 242: the shielding structure 31 has a semi-circular structure. The gate bonding pad 29 is located in the interval defined by the shielding structure 31 and the active region aa, the shielding structure 31 completely surrounds the gate bonding pad 29, in this way, the shielding structure 31 is electrically connected to the source 24 to effectively shield the silver ions in the chip silver paste that migrates to the gate 25 under the action of an electric field, and there is no need to separately set up a power supply to be electrically connected to the shielding structure 31, which may reduce complex wiring and reduce costs.

On the basis of the above-mentioned embodiment, the shielding structure 31 can correspond to a variety of different installation positions, under different installation positions, three feasible implementation manners will be described in detail below.

The shielding structure 31 may include a first shielding subsection 311, a second shielding subsection 312, and a third shielding subsection 313, and the second shielding subsection 312 is respectively connected to the first shielding subsection 311 and the third shielding subsection 313.

The second shielding subsection 312 is located in the scribe region 33, the first shielding subsection 311 is located in the working region 32 and is electrically connected to the first source 241, the third shielding subsection 313 is located in the working region 32 and is electrically connected to the Nth source:
or, the second shielding subsection 312 is located in the border area between the working region 32 and the scribe region 33, the first shielding subsection is located in the working region 32 and is electrically connected to the first source 241, the third shielding subsection 313 is located in the working region 32 and is electrically connected to the Nth source;
or, the first shielding subsection 311, the second shielding subsection 312, and the third shielding subsection 313 are all located in the working region 32, the first shielding subsection 311 is electrically connected to the first source 241, and the third shielding subsection 313 is electrically connected to the Nth source.

As a feasible implementation manner, continuing referring to FIG. 19, the shielding structure 31 may include a first shielding subsection 311, a second shielding subsection 312, and a third shielding subsection 313, and the second shielding subsection 312 is respectively connected to the first shielding subsection 311 and the third shielding subsection 313, and the second shielding subsection 312 is located in the scribe region 33. The first shielding subsection 311 is located in the working region 32 and is electrically connected to the first source 241, and the third shielding subsection 313 is located in the working region 32 and is electrically connected to the second source 242.

Specifically, the working region 32 may be understood as the region where the semiconductor device works, which includes the active region aa and the passive region bb: the active region aa may be understood as the region where two-dimensional electron gas, electrons or holes exist, and its working state and characteristics are affected by external circuits, which is the active working region of the semiconductor device. The passive region bb may be understood as the region outside the active region aa that participates in the operation of the device, but the working state is not affected by external circuits. The scribe region 33 refers to the region where a semiconductor device is diced and cut to form a plurality of independent semiconductor devices. The second shielding subsection 312 is located in the scribe region 33, that is, most of the shielding structure 31 is located in the scribe region 33; under the premise of shielding silver ions, it is ensured that the setting of the shielding structure 31 will not affect the normal operation of the semiconductor device, and ensure the stable performance of the semiconductor device.

As a feasible implementation manner, FIG. 14 is a top view schematic diagram illustrating another semiconductor device according to an embodiment of the present disclosure, and it is illustrated by taking N equal to 2 as an example. As shown in FIG. 14, the shielding structure 31 may include a first shielding subsection 311, a second shielding subsection 312, and a third shielding subsection 313, and the second shielding subsection 312 is respectively connected to the first shielding subsection 311 and the third shielding subsection 313, and the second shielding subsection 312 is located in the border area between the working region 32 and the scribe region 33. The first shielding subsection 311 is located in the working region 32 and is electrically connected to the first source 241. The third shielding subsection 313 is located in the working region 32 and is electrically connected to the second source 242.

Exemplarily, the second shielding subsection 312 is located in the border area between the working region 32 and the scribe region 33, the second shielding subsection 312 and the third shielding subsection 313 are both located in the working region 32, such setting ensures that the shielding structure 31 can effectively shield silver ions and ensure the normal operation of the semiconductor device, and at the same time ensure that the semiconductor device including the shielding structure 31 are relatively compact, which is beneficial to realize the miniaturization design of the semiconductor device.

As a feasible implementation manner, FIG. 17 is a top view schematic diagram illustrating another semiconductor device according to an embodiment of the present disclosure, and it is illustrated by taking N equal to 2 as an example. As shown in FIG. 17, the shielding structure 31 may include a first shielding subsection 311, a second shielding subsection 312, and a third shielding subsection 313, and the second shielding subsection 312 is respectively connected to the first shielding subsection 311 and the third shielding subsection 313.

The first shielding subsection 311, the second shielding subsection 312, and the third shielding subsection 313 are all located in the working region 32, the first shielding subsection 311 is electrically connected to the first source 241, and the third shielding subsection 313 is electrically connected to the second source 242.

Exemplarily, the first shielding subsection 311, the second shielding subsection 312, and the third shielding subsection 313 are all located in the working region 32 instead of being arranged in the scribe region 33. In this way, the semiconductor device including the shielding structure 31 can be arranged compactly, and the semiconductor device has a small volume, which is beneficial to realize the miniaturization design of the semiconductor device.

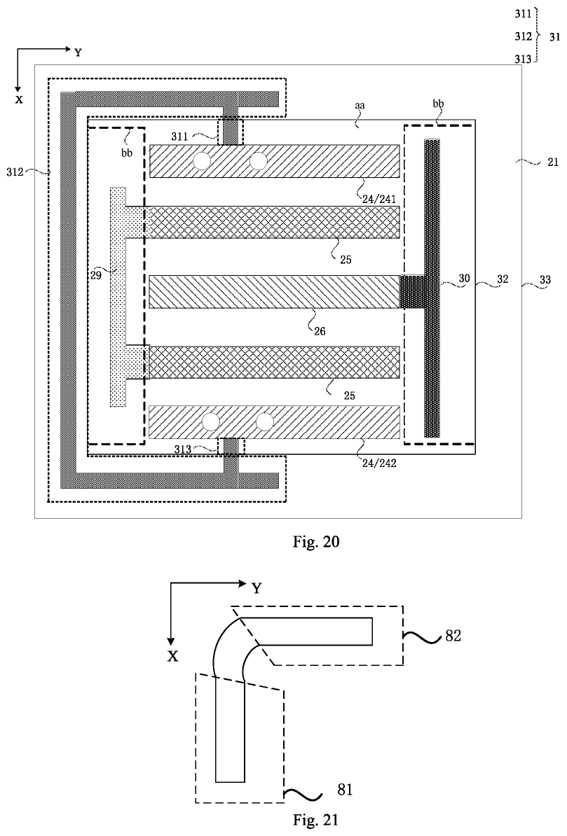

FIG. 20 is a top view schematic diagram illustrating another semiconductor device according to an embodiment of the present disclosure. As shown in FIG. 19, FIG. 14, FIG. 17, and FIG. 20, the shape of the connection between the first shielding subsection 311 and the second shielding subsection 312 may include an “L” shape or a “T” shape, and the shape of the connection between the third shielding subsection 313 and the second shielding subsection 312 may include an “L” shape or a “T” shape.

As shown in FIG. 19, FIG. 14, and FIG. 17, the shape of the connection between the first shielding subsection 311 and the second shielding subsection 312 includes an “L” shape. As shown in FIG. 20, the shape of the connection between the first shielding subsection 311 and the second shielding subsection 312 includes a “T” shape. The shape of the connection between the first shielding subsection 311 and the second shielding subsection 312 includes an “L” shape, that is, the shielding structure 31 is directly bent and connected to the source in the active region aa from one side of the gate bonding pad 29, and will not extend to the drain bonding pad 30. The shape of the connection between the first shielding subsection 311 and the second shielding subsection 312 includes a “T” shape, that is, the shielding structure 31 can extend toward the drain bonding pad 30 while being directly bent and connected to the source in the active region aa from one side of the gate bonding pad 29. The embodiment of the present disclosure is only described by taking two feasible implementation manners as examples, and does not limit the specific shape of the shielding structure 31, as long as the connection between the first shielding subsection 311 and the second shielding subsection 312 is effectively connected, the shielding effect of the shielding structure 31 will not be affected, and the stable performance of the semiconductor device can be effectively guaranteed.

FIG. 21 is a partial top view schematic diagram illustrating a shielding structure according to an embodiment of the present disclosure, the shielding structure 31 may include a first portion 81 extending along a first direction (X direction as shown in the drawing) and a second portion 82 extending along a second direction (Y direction as shown in the drawing): both the first direction and the second direction are parallel to the plane where the substrate 21 is located, and the first direction intersects the second direction; and the connection angle between the first portion 81 and the second portion 82 includes a chamfer or an arc angle.

Exemplarily, as shown in FIG. 21, the connection angle between the first portion 81 and the second portion 82 is an arc angle, and the connection angle between the first portion 81 and the second portion 82 of the shielding structure 31 is a chamfer or an arc angle, which may not only effectively shield silver ions during the packaging process, effectively shield and protect the gate bonding pad 29, but also effectively reduce the peak value of the electric field at the tip to ensure good performance of the semiconductor device.

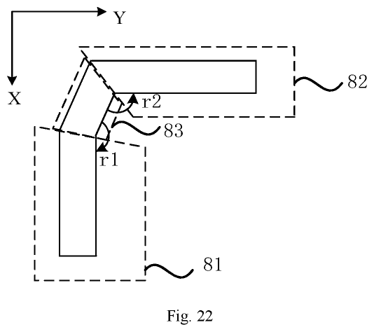

FIG. 22 is a partial top view schematic diagram illustrating another shielding structure according to an embodiment of the present disclosure. As shown in FIG. 22, the shielding structure 31 includes a first portion 81 extending along a first direction and a second portion 82 extending along a second direction: both the first direction and the second direction are parallel to the plane where the substrate is located, and the first direction intersects the second direction; and the shielding structure 31 further includes a third portion 83, the third portion 83 is respectively connected to the first portion 81 and the second portion 82, and the included angle r1 between the third portion 83 and the first portion 81 is an obtuse angle, and the included angle r2 between the third portion 83 and the second portion 82 is an obtuse angle.

Exemplarily, as shown in FIG. 22, the third portion 83 of the shielding structure 31 is connected to the first portion 81 and the second portion 82 respectively, and the angle r1 and the angle r2 as shown in FIG. 22 are formed respectively, through the reasonable connection of the first portion 81, the second portion 82 and the third portion 83, not only the silver ions can be effectively shielded during the packaging process, the gate bonding pad 29 can be effectively shielded and protected, but also the peak value of the electric field at the tip can be reduced, to achieve a reasonable distribution of the electric field and ensure good performance of the semiconductor device.

Continuing to refer to FIG. 19, the shielding structure 31 may include a first portion 81 extending along a first direction and a second portion 82 extending along a second direction, both the first direction and the second direction are parallel to the plane where the substrate is located, and the first direction intersects the second direction:
the semiconductor device includes a first boundary extending along a first direction and a second boundary extending along a second direction;
the minimum distance L1 between the first portion 81 and the first boundary satisfies L1>30 μm; and
the minimum distance L2 between the second portion 82 and the second boundary satisfies L2>30 μm.

Exemplarily, the minimum distance L1 between the first portion 81 and the first boundary and the minimum distance L2 between the second portion 82 and the second boundary both are controlled to be greater than 30 μm, which is beneficial to increase the migration distance of the silver ions in the patch silver paste to the gate bonding pad 29 under the action of the electric field, and further ensures that the shielding structure 31 has a good shielding effect.

Continuing referring to FIG. 19, the shielding structure 31 includes a first portion 81 extending along a first direction and a second portion 82 extending along a second direction; both the first direction and the second direction are parallel to the plane where the substrate is located, and the first direction intersects the second direction:
the extension width D1 of the first portion 81 in the second direction satisfies D1>10 μm; and
the extension width D2 of the second portion 82 in the first direction satisfies D2>10 μm.

Exemplarily, the extension width D1 of the first portion 81 of the shielding structure 31 in the second direction and the extension width D2 of the second portion 82 in the first direction are both greater than 10 μm. A reasonable extension width is conducive to ensuring the shielding effect of the shielding structure 31, otherwise, if the shielding effect is too poor, some silver ions will still migrate to the gate bonding pad, which will cause a gate-source short circuit, directly affecting the stable performance of the semiconductor device.

Continuing referring to FIG. 19, the minimum distance L3 between the vertical projection of the shielding structure 31 on the plane where the substrate 21 is located and the vertical projection of the gate bonding pad 29 on the plane where the substrate 21 is located satisfies L3>10 μm.

The minimum distance L4 between the vertical projection of the shielding structure 31 on the plane where the substrate 21 is located and the vertical projection of the drain bonding pad 30 on the plane where the substrate 21 is located satisfies L4>10 μm.

Exemplarily, the minimum distance L3 between the vertical projection of the shielding structure 31 on the plane where the substrate 21 is located and the vertical projection of the gate bonding pad 29 on the plane where the substrate 21 is located is greater than 10 μm, and the minimum distance L4 between the vertical projection of the shielding structure 31 on the plane where the substrate 21 is located and the vertical projection of the drain bonding pad 30 on the plane where the substrate 21 is located is greater than 10 μm: such setting can reduce the parasitic capacitance between the shielding structure 31 and the gate bonding pad 29 and the drain bonding pad 30, which may not only effectively shield silver ions during the packaging process, effectively shield and protect the gate bonding pad 29, but also ensure good performance of the semiconductor device.

On the basis of the above embodiment, the multi-layer semiconductor layer of the semiconductor device 20 provided by the embodiment of the present disclosure may specifically include a nucleation layer located on the substrate, a buffer layer located on one side of the nucleation layer away from the substrate, a channel layer located on one side of the buffer layer away from the nucleation layer, a barrier layer located on one side of the channel layer away from the buffer layer, wherein the barrier layer and the channel layer form a heterojunction structure, and a 2DEG (not shown in the drawing) is formed at the interface of the heterojunction.

Exemplarily, the material of the nucleation layer and the buffer layer can be a nitride, specifically GaN or AlN or other nitrides. The nucleation layer and buffer layer can be used to match the material of the base substrate 10 and the epitaxial channel layer. The material of the channel layer may be GaN or other semiconductor materials, such as InAlN. The barrier layer is located above the channel layer, and the material of the barrier layer may be any semiconductor material capable of forming a heterojunction structure with the channel layer, including gallium-based compound semiconductor materials or nitride-based semiconductor materials, such as InₓAl_{y}Ga_{z}N_{1-x-y-z}, where, 0≤x≤1, 0≤y≤1, 0≤z≤1. The channel layer and the barrier layer form a semiconductor heterojunction structure, and a high-concentration two-dimensional electron gas is formed at the interface of the channel layer and the barrier layer.

It should be understood that the embodiments of the present disclosure improve the output power of the semiconductor device from the perspective of semiconductor device structure design. The semiconductor device includes, but is not limited to high-power gallium nitride High Electron Mobility Transistor (HEMT), Silicon-On-Insulator (SOI) structure transistor, gallium arsenide (GaAs)-based transistor and Metal-Oxide-Semiconductor Field-Effect Transistor (MOSFET), Metal Insulator Semiconductor Field-Effect Transistor (MISFET), Double Heterojunction Field-Effect Transistor (DHFET), Junction Field-Effect Transistor (JFET), Metal-Semiconductor Field-Effect Transistor (MESFET), Metal-Semiconductor Heterojunction Field-Effect Transistor (MISHFET) or other field-effect transistors working in a high-voltage and high-current environment.

Based on the same inventive concept, an embodiment of the present disclosure further provides a method of manufacturing a semiconductor device, and the method of manufacturing a semiconductor device provided in the embodiment of the present disclosure may include:

S301, providing a substrate.

Exemplarily, the material of the substrate may be Si, SiC, gallium nitride or sapphire, or other materials suitable for growing gallium nitride.

S302, forming a multi-layer semiconductor layer on one side of the substrate.

Exemplarily, the multi-layer semiconductor layer is located on one side of the substrate, and the multi-layer semiconductor layer may specifically be a III-V compound semiconductor material, and 2DEG is formed in the multi-layer semiconductor layer.

S303, forming a gate on one side of the multi-layer semiconductor layer away from the substrate, and in the active region.

S304, forming at least one bonding pad on one side of the multi-layer semiconductor layer away from the substrate, and in the passive region, wherein the bonding pad includes at least a gate bonding pad, and the gate bonding pad is electrically connected to the gate.

S305, forming at least one shielding structure on one side of the multi-layer semiconductor layer away from the substrate, wherein the shielding structure includes a gate shielding structure, and the gate shielding structure is for shielding and protecting the gate bonding pad.

By forming a shielding structure on one side of the multi-layer semiconductor layer away from the substrate, a shielding structure is provided, which effectively shields the silver ions in the patch silver paste from migrating to the bonding pad during the packaging process, ensures the stable performance of the bonding pad and the electrode connected to the bonding pad, avoids the short circuit between the bonding pad and the electrode connected to the bonding pad and the source, and ensures the normal operation of the semiconductor device.

It is to be noted that that the above are only example embodiments of the present disclosure and applied technical principles. Those skilled in the art will appreciate that the present disclosure is not limited to the specific embodiments described herein. Various obvious changes, rearrangements, and substitutions will be apparent to those skilled in the art without departing from the scope of the present disclosure. Therefore, although the present disclosure has been described in more detail through the above embodiments, the present disclosure is not limited to the above embodiments. Further other equivalent embodiments may be included without departing from the concept of the present disclosure, and the scope of the present disclosure is determined by the scope of the appended claims.

1. A semiconductor device comprising an active region and a passive region surrounding the active region, the semiconductor device further comprising:
a substrate;
a multi-layer semiconductor layer located on one side of the substrate; and
at least one shielding structure located on one side of the substrate, the shielding structure electrically connected to a preset potential, for forming i) an electric field or ii) a zero electric field of the active region pointing toward the passive region.

2. The semiconductor device according to claim 1, comprising a working region and a scribe region surrounding the working region, the working region comprising the active region and the passive region, wherein the semiconductor device further comprises:
at least one bonding pad located on one side of the multi-layer semiconductor layer opposite the substrate, and located in the passive region; and
the shielding structure is for shielding and protecting the bonding pad, and the preset potential is greater than or equal to 0;
wherein the multi-layer semiconductor layer comprises a conductive region located in the passive region and a two-dimensional electron gas elimination region, the two-dimensional electron gas elimination region is located between the conductive region as the shielding structure, and the active region; and/or
wherein the semiconductor device further comprises a dielectric layer located on one side of the multi-layer semiconductor layer opposite the substrate, and at least one conductive trace as the shielding structure, located on one side of the dielectric layer opposite the multi-layer semiconductor layer.

3. (canceled)

4. The semiconductor device according to claim 2, wherein the shielding structure comprises a first shielding subsection, a second shielding subsection, and a third shielding subsection, and wherein the first shielding subsection is located on one side of the passive region opposite the active region:
wherein the first shielding subsection is electrically connected to the second shielding subsection and the third shielding subsection respectively, and wherein an extending direction of the first shielding subsection intersects both an extending direction of at least part of the second shielding subsection and an extending direction of at least part of the third shielding subsection; and
wherein the shielding structure is located on at least three sides of the passive region opposite the active region.

5. The semiconductor device according to claim 2, wherein the shielding structure comprises a fourth shielding subsection extending along a first direction and a fifth shielding subsection extending along a second direction, and wherein the first direction and the second direction intersect and are both are parallel to the plane where the substrate is located:
wherein the fourth shield subsection comprises a plurality of first sub-shielding structures, wherein two of the first sub-shielding structures adjacent along the first direction are arranged staggered in the second direction, wherein vertical projections on the first plane overlap, and wherein the first plane is parallel to the first direction and perpendicular to the plane where the substrate is located; and/or
wherein the fifth shield subsection comprises a plurality of second sub-shielding structures, wherein two of the second sub-shielding structures adjacent along the second direction are arranged staggered in the first direction, wherein vertical projections on the second plane overlap, and wherein the second plane is parallel to the second direction and perpendicular to the plane where the substrate is located.

6. The semiconductor device according to claim 2, wherein at least part of the shielding structure is not provided with a dielectric layer on one side opposite the substrate;
wherein the multi-layer semiconductor layer comprises a conductive region located in the passive region and a two-dimensional electron gas elimination region; and
wherein i) the conductive region is a two-dimensional electron gas forming region or ii) a semiconductor doped region.

7. (canceled)

8. The semiconductor device according to claim 2, wherein the semiconductor device further comprises a gate located on one side of the multi-layer semiconductor layer opposite the substrate, and located in the active region, and a drain located on one side of the multi-layer semiconductor layer opposite the substrate, and located in the active region,
wherein the bonding pad comprises a gate bonding pad electrically connected to the gate and a drain bonding pad electrically connected to the drain; and
wherein at least one shielding structure comprises a gate shielding structure for shielding and protecting the gate bonding pad and/or a drain shielding structure for shielding and protecting the drain bonding pad.

9. The semiconductor device according to claim 2, wherein the shielding structure extends from the passive region to the active region.

10. The semiconductor device according to claim 2, wherein the active region further comprises a plurality of fixed potential structures, wherein each fixed potential structure comprises a source, and wherein the shielding structure is electrically connected to a source of the active region,
wherein the source comprises a first source and an Nth source arranged along a first direction, wherein the first direction is parallel to the plane where the substrate is located, wherein the first source is located at a first end of the active region, wherein the Nth source is located at a second end of the active region, and wherein the first end and the second end is disposed opposite to each other along the first direction; and
wherein the shielding structure is electrically connected to the first source and the Nth source respectively, and wherein the gate bonding pad is located in an interval defined by the shielding structure and the active region.

11. The semiconductor device according to claim 10, wherein the source is electrically connected to a source back electrode through a via hole:
wherein an overlapping area of the vertical projection of the shielding structure on the plane where the substrate is located and the vertical projection of the via hole on the plane where the substrate is located is S1;
wherein the vertical projection area of the via hole on the plane where the substrate is located is S2; and
wherein S1<S2/4.

12. The semiconductor device according to claim 11, wherein the vertical projection of the shielding structure on the plane where the substrate is located does not overlap with the vertical projection of the via hole on the plane where the substrate is located.

13. The semiconductor device according to claim 10, wherein the shielding structure comprises a first shielding subsection, a second shielding subsection, and a third shielding subsection, wherein the second shielding subsection is connected to the first shielding subsection and the third shielding subsection respectively; and
wherein the second shielding subsection is located in the scribe region, wherein the first shielding subsection is located in the working region and is electrically connected to the first source, and wherein the third shielding subsection is located in the working region and is electrically connected to the Nth source.

14. The semiconductor device according to claim 13, wherein the semiconductor device further comprises a first dielectric layer located on one side of the multi-layer semiconductor layer opposite the substrate, and located in the passive region:
wherein the first shielding subsection and the third shielding subsection both are located on one side of the first dielectric layer opposite the substrate; and
wherein along a direction perpendicular to the substrate, thickness of the shielding structure is greater than that of the first dielectric layer, so that the first shielding subsection and the third shielding subsection both are electrically connected to the second shielding subsection.

15. The semiconductor device according to claim 13, wherein the semiconductor device further comprises a first dielectric layer located on one side of the multi-layer semiconductor layer opposite the substrate, and located in the passive region; and
wherein along a direction perpendicular to the substrate, a thickness of the source is greater than that of the first dielectric layer, so that the first shielding subsection and the third shielding subsection both are electrically connected to the source.

16. The semiconductor device according to claim 15, wherein the semiconductor device further comprises a second dielectric layer located in the working region:
wherein the second dielectric layer covers the first shielding subsection, the third shielding subsection, and the source; and
wherein in the direction perpendicular to the substrate, a sum of thicknesses of the first dielectric layer, the first shielding subsection, and the second dielectric layer is greater than a thickness of the source, so that the second dielectric layer located on one side of the first shielding subsection opposite the substrate is connected to the second dielectric layer located on one side of the source opposite the substrate.

17. The semiconductor device according to claim 10, wherein the shielding structure comprises a first shielding subsection, a second shielding subsection, and a third shielding subsection, and wherein the second shielding subsection is connected to the first shielding subsection and the third shielding subsection respectively; and
wherein the first shielding subsection, the second shielding subsection, and the third shielding subsection are all located in the working region, wherein the first shielding subsection is electrically connected to the first source, and wherein the third shielding subsection is electrically connected to the Nth source.

18. The semiconductor device according to claim 17, wherein the semiconductor device further comprises at least one dielectric layer located on one side of the multi-layer semiconductor layer opposite the substrate, and located in the passive region:
wherein at least one of the dielectric layers comprises a first surface on one side of the multi-layer semiconductor layer opposite the substrate;
wherein the shielding structure comprises a second surface on one side of the multi-layer semiconductor layer opposite the substrate; and
wherein along a direction perpendicular to the substrate, the second surface is located on one side of the first surface opposite the substrate.

19. The semiconductor device according to claim 10, wherein the source comprises a multi-layer source metal layer; and
wherein i) the shielding structure comprises a one-layer shielding metal layer, and the shielding metal layer and one side of the multi-layer source metal layer are provided on the same layer and made of the same material, or ii) the shielding structure comprises a multi-layer shielding metal layer, and the multi-layer shielding metal layer corresponds to the multi-layer source metal layer one by one, and the shielding metal layer and the source metal layer set correspondingly are provided on the same layer and made of the same material.

20. The semiconductor device according to claim 1, wherein the shielding structure comprises a first portion extending along a first direction and a second portion extending along a second direction, wherein the first direction and the second direction both are parallel to the plane where the substrate is located, and wherein the first direction intersects the second direction:
wherein the semiconductor device comprises a first boundary extending along the first direction and a second boundary extending along the second direction;
wherein a minimum distance L1 between the first portion and the first boundary satisfies L1>30 μm; and
wherein a minimum distance L2 between the second portion and the second boundary satisfies L2>30 μm.

21. The semiconductor device according to claim 1, wherein the shielding structure comprises a first portion extending along a first direction and a second portion extending along a second direction, wherein the first direction and the second direction both are parallel to the plane where the substrate is located, and wherein the first direction intersects the second direction;
wherein a extension width D1 of the first portion in the second direction satisfies D1>10 μm; and
wherein a extension width D2 of the second portion in the first direction satisfies D2>10 μm.

22. The semiconductor device according to claim 8, wherein the minimum distance L3 between the vertical projection of the shielding structure on the plane where the substrate is located and the vertical projection of the gate bonding pad on the plane where the substrate is located satisfies L3>10 μm; and
wherein a minimum distance L4 between the vertical projection of the shielding structure on the plane where the substrate is located and the vertical projection of the drain bonding pad on the plane where the substrate is located satisfies L4>10 μm.

23. (canceled)
